(19) United States
(12) Patent Application Publication
(10) Pub. No.: US 2024/0120170 A1
(43) Pub. Date: Apr. 11, 2024

(54) HIGH VOLTAGE PLASMA CONTROL

(71) Applicant: Eagle Harbor Technologies, Inc., Seattle, WA (US)

(72) Inventors: Timothy Ziemba, Bainbridge Island, WA (US); Kenneth Miller, Seattle, WA (US)

(21) Appl. No.: 18/477,174

(22) Filed: Sep. 28, 2023

Related U.S. Application Data
(60) Provisional application No. 63/411,600, filed on Sep. 29, 2022.

(51) Int. Cl. H01J 37/24; H01J 37/32; H02M 3/335

(52) U.S. Cl. CPC H01J 37/241; H01J 37/32422; H02M 3/33573

(57) ABSTRACT

A high voltage pulsing power system is disclosed that include a DC power supply, a switch circuit electrically coupled with the DC power supply, a droop control circuit coupled with the switch circuit, and/or an output. The switch circuit includes a plurality of switch modules and produces a plurality of pulses. The droop control circuit includes a droop diode, a droop inductor, and a droop element. The droop diode may be electrically coupled in series between the switch circuit and the transformer primary that allows the negative pulse portion of the pulses to pass from the switching circuit to the transformer primary. The droop inductor and he droop element may be arranged in series across the droop diode to allow the negative pulse portion of the pulses to pass from the switching circuit to the transformer primary and/or store energy from the negative pulse portion of the pulses.

### BACKGROUND

The application of RF-excited gaseous discharges in thin film and semiconductor fabrication technology has become standard. Positive ions produced in the plasma volume are accelerated across the plasma sheaths and arrive at electrodes with an Ion Energy Distribution Function (ion energy distribution function), which is determined by the magnitude and the waveform of the time dependent potential difference across the sheaths, the gas pressure, the physical geometry of the reactor, and/or other factors. This ion bombardment energy distribution may determine the degree of anisotropy in thin-film etching, the amount of ion impact induced damage to surfaces, the aspect ratio and/or diameter and/or depth of holes and other etched features, the rate at which features are etched, etc. Control of the ion energy distribution function is of great importance to processes involving plasma etching.

High voltage power systems are required to create the needed potentials that accelerate the ions within the plasma. The high voltage power systems may provide power waveforms that are well shaped (e.g., substantially flat between pulses) to create various desired ion energy distribution functions. Different waveforms may be used pulse to pulse, each potentially producing different ion energy distribution functions, such that in time a completely different and aggregate effective ion energy distribution function is created. Controlling the ion energy distribution function allows specific features of the etch process to be controlled.

In some applications, the chamber or plasma can modify portions of the waveform that are creating the ion energy distribution function. For example, in a semiconductor processing system, an ion current within the plasma may create a droop between consecutive pulses in the waveform at the wafer. These waveform modifications can directly affect and/or change the desired ion energy distribution function, thus decreasing the effectiveness of any processes within the chamber. For example, pulse to pulse droop tends to broaden the ion energy distribution function, and introduce more low energy ions.

### SUMMARY

A high voltage pulsing power system is disclosed. The high voltage pulsing power system includes a DC power supply, a switch circuit electrically coupled with the DC power supply, a droop control circuit coupled with the switch circuit, and an output. The output, for example, may be coupled with a plasma chamber. The high voltage pulse power system may also include an energy recovery circuit. The switch circuit can include a plurality of switch modules arranged in a full bridge, half bridge, or other bridge configuration, and may produce a plurality of pulses having a positive pulse portion and a negative pulse portion. The transformer can include a transformer core, primary windings, and secondary windings. The droop control circuit may include a droop diode, a droop inductor, and/or a droop element that may be a resistive element or an energy recovery circuit. The energy recovery circuit, for example, may be any collection of electrical components typically found in a DC to DC converter that moves energy from one potential to another potential.

The droop element, for example, may be any component or combination of components that is used to regulate how much current flows through the droop inductor. The droop element may work by limiting the energy that is injected into the droop inductor such that either an equilibrium current can be maintained, or a specified current can be maintained. A passive droop element such as a fixed resistor allows for steady equilibrium currents to be maintained, while an active droop element allows the current flowing through the droop inductor to be varied in time. The droop diode may be electrically coupled in series between the switch circuit and the primary winding of the transformer, and/or may allow for the positive pulse portion of the plurality of pulses to pass from the switching circuit to the primary winding of the transformer. Inductance in series with the droop diode may be specifically selected to realize positive pulses with a particular shape. The inductance in series with the droop diode may be set such that the positive going pulse has a clean rounded sinusoidal like shape, without notches, divots, or multiple peaks/ringing. The droop inductor and the droop element may be arranged in series across the droop diode to allow the negative pulse portion of the plurality of pulses to pass from the switching circuit to the primary winding of the transformer. The combination of the droop inductor and droop element may govern how much energy is stored in the droop inductor and/or how much current is flowing through the droop inductor. The current that flows through the droop inductor may be intimately related to a voltage applied across the plasma and/or the ion energy distribution function that is created. The disclosed high voltage pulsed power system, for example, can change its output in time, either pulse to pulse, and/or burst to burst, and/or train to train to create both different and time varying composite ion energy distribution functions.

The various embodiments described in the summary and this document are provided not to limit or define the disclosure or the scope of the claims.

### BRIEF DESCRIPTION OF THE FIGURES

FIG. 1 is a circuit diagram of a high voltage pulsing power supply and plasma system.

FIG. 2A and FIG. 2B show output waveforms from the high voltage pulsing power supply and plasma system shown in FIG. 1.

FIG. 3A and FIG. 3B show output waveforms from the high voltage pulsing power supply and plasma system shown in FIG. 1.

FIG. 4 is a circuit diagram of a high voltage pulsing power supply and plasma system.

FIG. 5A and FIG. 5B show output waveforms from the high voltage pulsing power supply and plasma system shown in FIG. 4.

FIG. 6A and FIG. 6B show output waveforms from the high voltage pulsing power supply and plasma system shown in FIG. 4.

FIG. 7 is a circuit diagram of a high voltage pulsing power supply and plasma system with an energy recovery circuit.

FIG. 8A and 8B show output waveforms from the high voltage pulsing power supply and plasma system shown in FIG. 7.

FIG. 9 show output waveforms from the high voltage pulsing power supply and plasma system shown in FIG. 7.

FIG. 10A and 10B show output waveforms from the high voltage pulsing power supply and plasma system shown in FIG. 7.

FIG. 11 show output waveforms from the high voltage pulsing power supply and plasma system shown in FIG. 7.

FIG. 12 is a circuit diagram of a high voltage pulsing power supply and plasma system with an active droop control circuit.

FIG. 13 shows output waveforms from the high voltage pulsing power supply and plasma system shown in FIG. 12.

FIG. 14A shows output waveforms from the high voltage pulsing power supply and plasma system shown in FIG. 12.

FIG. 14B shows the switching logic used to produce the waveforms shown in FIG. 14A.

FIG. 15A shows output waveforms from the high voltage pulsing power supply and plasma system shown in FIG. 12.

FIG. 15B shows output waveforms from the high voltage pulsing power supply and plasma system shown in FIG. 12.

FIG. 16A shows output waveforms from the high voltage pulsing power supply and plasma system shown in FIG. 12.

FIG. 16B shows the switching logic used to produce the waveforms shown in FIG. 16A.

FIG. 17A shows zoomed in views of the waveform shown in FIG. 16A

FIG. 17B shows zoomed in views of the waveform shown in FIG. 16A.

FIG. 17C shows zoomed in views of the waveform shown in FIG. 16A.

FIG. 17D shows zoomed in views of the waveform shown in FIG. 16A.

FIG. 18 shows the ion energy distribution for ions within an example chamber of the high voltage pulsing power supply and plasma system shown in FIG. 12.

FIG. 19 shows the ion energy distribution for ions within an example chamber of the high voltage pulsing power supply and plasma system shown in FIG. 12.

FIG. 20A shows a low end energy distribution function.

FIG. 20B shows a high end energy distribution function.

FIG. 21 is a circuit diagram of a high voltage pulsing power supply and plasma system with a droop control circuit, and an energy control circuit.

FIG. 22 shows the ion energy distribution for ions within the high voltage pulsing power supply and plasma system shown in FIG. 21.

FIG. 23A shows a low end of the ion energy distribution.

FIG. 23B shows a high end of the ion energy distribution.

FIG. 24 shows a circuit diagram of a high voltage pulsing power supply and plasma system with an active droop control circuit.

FIG. 25 is a flowchart of an example process for controlling the voltage droop on a wafer between pulses.

FIG. 25 is a flowchart of an example process for controlling the ion energy distribution on a wafer.

FIG. 26 is an illustration of an example waveform showing two bursts of pulses.

FIG. 27 is a block diagram of a computational system that can be used to with or to perform some embodiments described in this document.

### DETAILED DESCRIPTION

A high voltage pulsing power supply that produces high voltage pulses is disclosed. A high voltage pulsing power supply, for example, may be coupled with 1 or more plasma chambers. A high voltage pulsing power supply, for example, may compensate for voltage droop on a wafer in a plasma processing chamber. A high voltage pulsing power supply, for example, may provide energy recovery within a pulsing circuit. A high voltage pulsing power supply, for example, may allow narrow or specific ion energy distributions (“ion energy distribution function”) to be created in a plasma. A high voltage pulsing power supply, for example, may allow for a wide range of ion energy distribution functions to be created in a plasma. A high voltage pulsing power supply, for example, may allow for time varying ion energy distribution functions to be created in a plasma. A high voltage pulsing power supply, for example, may allow for operation at many different wafer voltage levels that may be varied in time (“multilevel control”) and/or the duration of either or both the positive or negative portion of the pulse may vary over time, among other things.

A pulse is a high voltage waveform that typically includes voltage at first voltage, peaks quickly to a second voltage for a short period of time, then returns to about the first voltage. A pulse may be positive or negative or bipolar (both positive and negative). A pulse may have a pulse width (e.g., full width, half maximum), an amplitude (e.g., the second voltage), a rise time (e.g., the time it takes for the waveform to change from the first voltage to a second voltage), and/or a fall time (e.g., the time it takes for the waveform to change from the second voltage back to the first voltage).

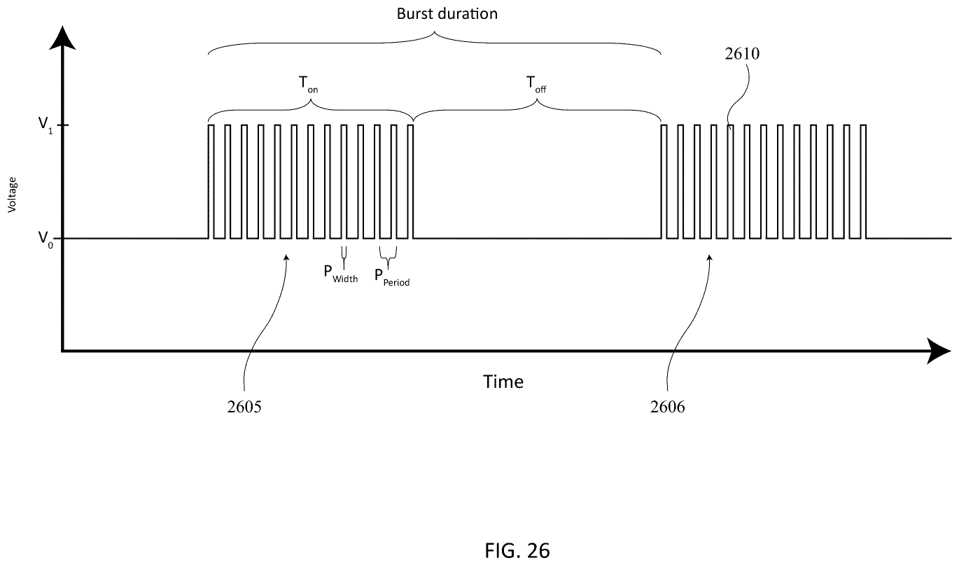

A burst (or a burst of pulses) is a series of pulses. A train (or pulse train) is a plurality of bursts. FIG. 26 shows an example of a pulse train with two bursts. Each burst has at least a pulse repetition frequency, a burst duration, and/or a burst period.

A high voltage pulsing power supply may compensate for voltage droop (e.g., a slope in the voltage between pulses) on a wafer in a plasma processing chamber. The voltage droop, for example, may be partially eliminated, fully eliminated, partially reversed, and/or fully reversed. For example, a wafer with a peak negative voltage of −6 kV may have a voltage droop of −2 kV by the end of the negative portion of the pulse. A high voltage pulsing power supply, for example, may hold the wafer voltage constant at around −6 kV for the entire portion of the negative pulse, a majority of the negative pulse, or a partial portion of the negative pulse, after which the wafer voltage droops. A high voltage pulsing power supply, for example, may also allow the wafer voltage to be ramped more negative in time such that the wafer voltage changes from −6 kV to −10 kV during the negative portion of the pulse. A high voltage pulsing power supply, for example, may work in the range from ±100 V to ±100 kV. This voltage range may include both the absolute voltage range applied to the wafer, as well as the range over which the power supply can alter the voltage from that which would be attributed to wafer droop. A high voltage pulsing power supply, for example, may control the negative wafer voltage for voltages greater than 100 V.

The average power delivered by a high voltage pulsing power supply, averaged across many bursts and/or trains, for example, may be greater than 10 W, 100 W, 1000 W, or 100 kW. The typical average power delivered by a high voltage pulsing power supply, for example, may be greater than 1 kW. The power delivered by a high voltage pulsing power supply averaged across a single burst, for example, may be 1×, 5×, or 30× the average power delivered.

The duration of the droop control (e.g., the wafer waveform control) of the negative portion of the pulse, for example, can operate for a duration of 100 ns, 1 μs, 10 μs, 100 μs, and/or 1 ms.

The positive portion of a pulse, for example, may be used to collapse the sheath/electron potential and sweep electrons onto a wafer within a plasma processing chamber to neutralize the charge that accumulated as ion current flow to the wafer during a negative portion of the pulse. The positive portion of the pulse, for example, may operate for a duration of about 100 ns, 1 μs, 10 μs, 100 μs, and/or 1 ms. The width and/or rise time of the positive portion of the pulse, for example, may be used to control the plasma potential relaxation time and the degree of ionization, among other plasma properties.

A high voltage pulsing power supply may control the ratio of the positive portion of the pulse to the negative portion of the pulse. This ratio, for example, may range from 1% to 100%. This ratio, for example, may be set to control the magnetic flux within a transformer core, to control various plasma properties such as how the positive and negative plasma sheaths are formed and collapsed, how much negative charge is transferred to the wafer during the positive portion of the pulse, and/or how much etching of the chamber wall occurs during the positive portion of the pulse, etc. This ratio may be set to optimize individual or multiple aspects of the etch process and features. For example, if features with small size and a high aspect ratio are desired, the ratio may be set to the smaller end of its range, where the positive portion of the pulse is much shorter than the negative portion of the pulse. The ratio may be adjusted to keep the magnetic flux within a transformer core below 1T

A high voltage pulsing power supply may produce high voltage pulses with plasma ion currents between about 10 mA and about 300 A. A high voltage pulsing power supply may produce high voltage pulses with chucking capacitance (e.g., as represented by capacitor 12) between about 0.3 nF and about 1,000 nF. A high voltage pulsing power supply may produce high voltage pulses in plasmas with a neutral density between about 0.1 mT and about 1,000 mT and/or composed of a single gas species or a variety of gas species. A high voltage pulsing power supply may produce high voltage pulses in plasmas that have an ionization of 10¹⁵-10¹⁹ particles per meter cubed. A high voltage pulsing power supply may produce high voltage pulses in a wide range of plasma conditions and/or chamber types.

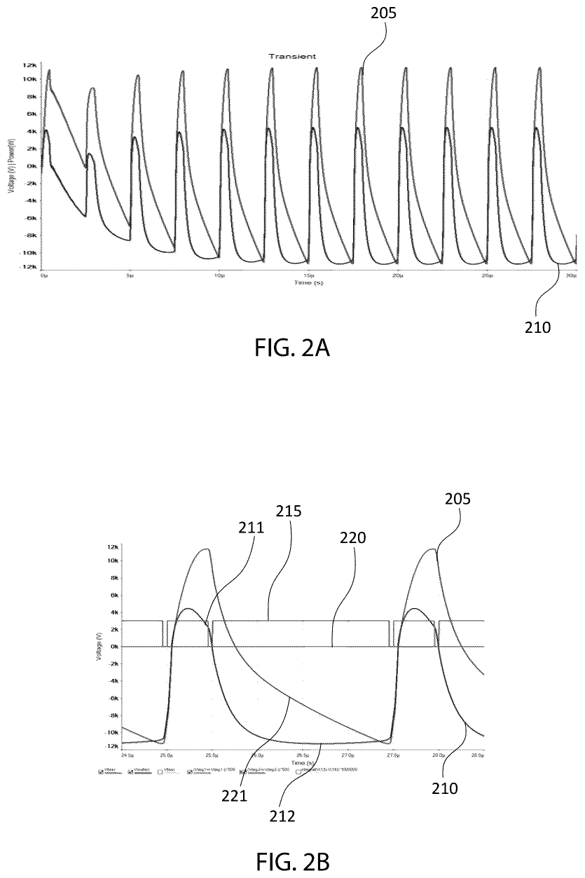

The inductor 184, which is in series with droop diode 183, for example, may help produce positive pulses with a particular shape. The inductor 184 in series with the droop diode 183 may be set so the positive going pulse has a clean rounded sinusoidal like shape, such as, for example, without notches, divots, or multiple peaks/ringing as shown in the pulses oh waveform 210 in FIG. 2. The inductor 184, for example, may range between about 0.1 nH and about 10 pH as measured on the primary side of the transformer. The inductor 184 may include and/or include only parasitic stray inductances (no physical components. The inductor 184, for example, may be less than about 100 nH.

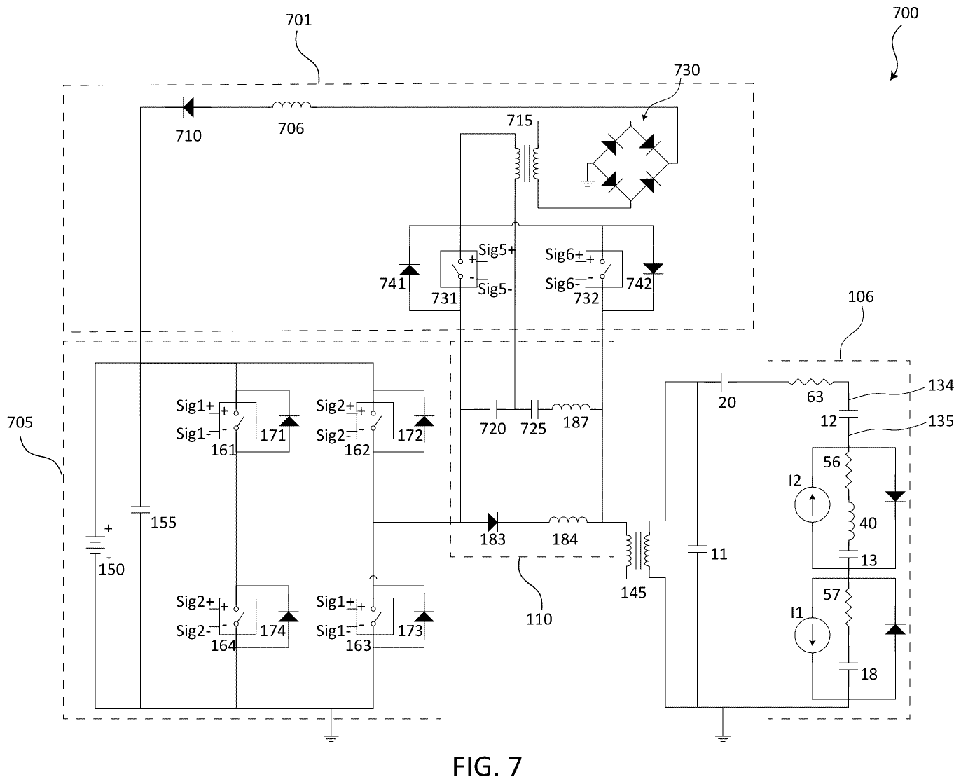

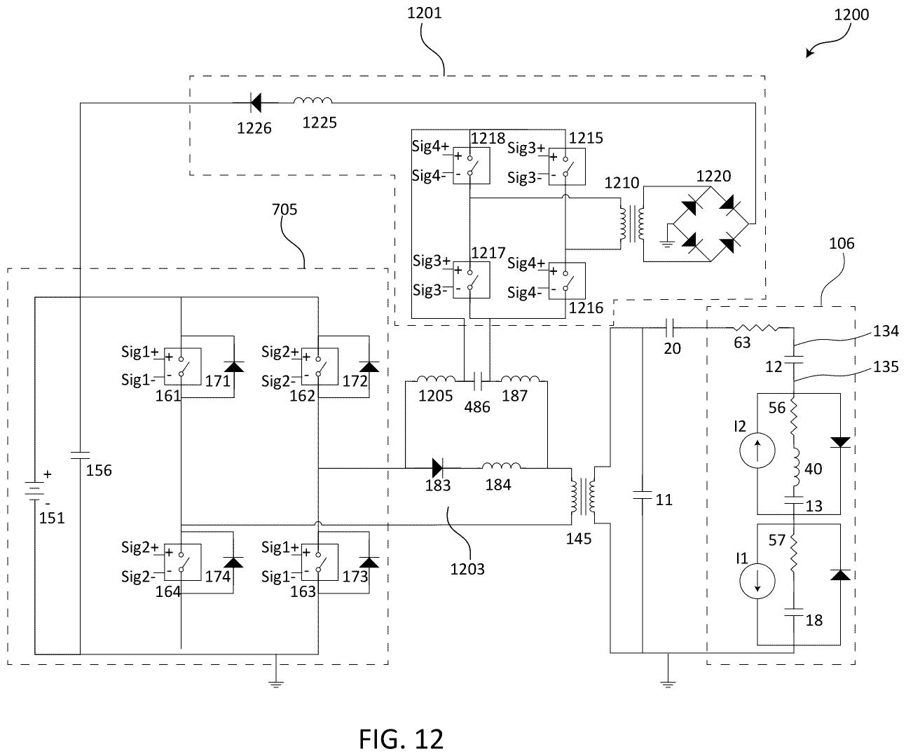

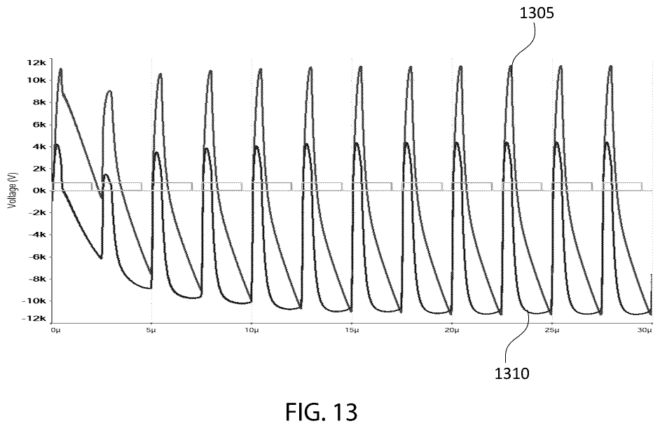

A high voltage pulsing power supply may include an energy recovery circuit (e.g., as shown in FIG. 7 and FIG. 12). The energy recovery circuit, for example, may include a DC to DC converter (e.g., rectification bridge 730) that transitions energy from one voltage level to another. The energy recovery circuit, for example, may operate with voltages between about 1 V and about 5,000 V. The energy recovery circuit, for example, may operate with power levels between about 10 W and 100 kW. The energy recovery circuit, for example, may behave as a simple DC-DC converter operating between two fixed voltages that remain constant in time or that vary in time. The time it takes the DC-DC converter to adjust the voltage ranges between which it operates ranges from about 1 μs to about 1 ms. The DC-DC converter, for example, may be based on various bridge topologies such as the half bridge or full bridge, among many possible topologies. The energy recovery circuit, for example, may recover energy from the circuit (e.g., the droop inductor) that would otherwise be lost. While recovering this energy, the energy recovery circuit, for example, can adjust the current flowing through the droop inductor and/or adjust the voltage waveform and/or amplitude applied to the wafer and/or to the plasma.

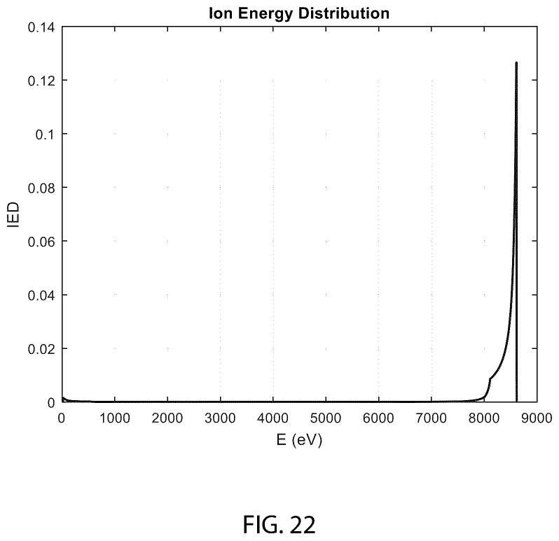

A high voltage pulsing power supply, for example, may produce narrow ion energy distribution functions within the plasma by reducing and/or eliminating the wafer voltage droop. For example, a uniform voltage maintained across the plasma may produce a narrow ion energy distribution function. As a high voltage pulsing power supply varies the voltage waveform applied to a plasma, a wide range of ion energy distribution functions can be created within the plasma that may, for example, range from those that are very peaked (e.g., see FIG. 22) to those that are flat, and those that are similar to the ion energy distribution functions created by standard sinusoidal power supplies used for plasma etch.

As another example, a high voltage pulsing power supply may produce time varying ion energy distribution functions. For example, a high voltage pulsing power supply may adjust wafer voltage and/or a wafer waveform (e.g., pulse width, pulse repetition frequency, pulse-to-pulse period, etc.) from pulse to pulse, burst to burst, and/or pulse train to pulse train. A series of pulses, for example, each of which has a peaked ion energy distribution function in a different location, could be combined to create a composite ion energy distribution function that is largely flat. Such composite ion energy distribution functions can be created, for example, from any arbitrary number of pulses containing any arbitrary distribution of waveforms, voltages, and/or ion energy distribution functions.

A high voltage pulsing power supply can create any composite ion energy distribution function. The ion energy distribution functions can be programmed and/or adjusted in real time to optimize various wafer etch parameters or ion energy distribution function parameters such as, for example, etch rate, mask erosion rate, feature aspect ratio, feature bow growth rate, feature profile, feature size, bottom hole diameter, etc. ion energy distribution functions may be created, for example, where for example 90% of the ions fall within a band representing 10% of the total width of the energy distribution and/or where the distribution is nearly flat across its entire range. ion energy distribution functions can be varied, for example, on timescales down to 100 ns, or timescales between about 10 μs and about 100 μs. The rate at which the ion energy distribution function can be varied may, for example, be set by the rate at which an energy recover circuit can adjust the DC voltage levels at which the high voltage pulsing power supply operates.

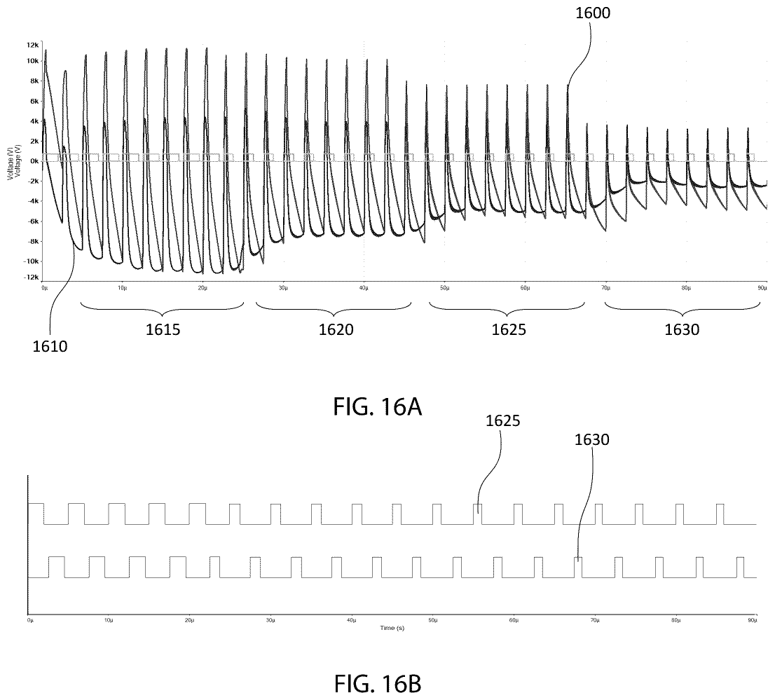

A high voltage pulsing power supply may allow for operation at many different wafer voltage levels (or voltage states) that vary in time in discrete bursts or trains as shown in FIG. 16A. Such operation may be referred to as multilevel control or bilevel control.

Droop in a plasma chamber, for example, may occur as current flows during the negative portion of an applied waveform (e.g., droop 221 shown in FIG. 2B).This droop, for example, charges a plasma facing surface and/or discharges a series capacitance, which may result in the voltage seen by the plasma falls in time. This often occurs, for example, during semiconductor plasma etch processes as the etch current flows to the wafer surface and reduces the voltage across the chucking capacitance. As the voltage across the chucking capacitance falls, so does the etch voltage (i.e. the voltage applied across the plasma).

Voltage droop may be governed by the equation

$$I = C \frac{dV}{dt}$$

where I am the plasma current flowing into the plasma, and C is the series capacitance (e.g., the wafer chucking capacitance (e.g., capacitor 12)). And dV/dt is the rate at which the voltage across the series capacitance changes due to the flow of the plasma current during the etch process. As plasma current flows into the series capacitance, it discharges the voltage that was established at the start of the pulse when the series capacitance was charged, in accordance with the equation

$$I = C \frac{dV}{dt} .$$

A high voltage pulsing power supply may operate in a way to cancel the droop in voltage seen across the series capacitance and the plasma, for example, by preventing the series capacitance from being discharged. It may do this by applying a ramped voltage to the opposite side of the relevant series capacitance that effectively cancels the dV/dt droop in voltage caused by the flow of ion current, and thus maintains a constant voltage across both the series capacitance and the plasma.

To cancel the voltage droop caused by the ion and/or etch current, a high voltage pulsing power supply may create an additional voltage droop and/or voltage change on the opposite side of the series capacitance to cancel the voltage droop that would otherwise happen. The droop inductor (e.g., droop inductor 187) may, for example, establish the ramped voltage needed to maintain a constant plasma voltage between pulses.

If the droop inductor is sized to maintain a relatively constant current during a pulse, for example, where the current matches the plasma ion and/or etch current, then the natural operation of the droop inductor imposes the needed dV/dt on the opposite side of the series capacitance such that the voltage across both the plasma and series capacitance remains constant. In as much as the current flowing through the droop inductor deviates from the ion current that is flowing in the plasma during the negative portion of the pulse, then the corresponding voltage drop across the plasma and ion energy distribution function will be consequently changed. The current that flows through the droop inductor may set both the voltage and/or the voltage waveform seen across the plasma.

A high voltage pulsing power supply may control the current that flows through the droop inductor. The droop inductor, for example, may include a physical element such as an inductor and/or stray inductance in other circuit elements. The droop inductor and/or the energy recovery circuit may control the current that flows through the droop inductor.

The size of the droop inductor may be set anywhere in the range between about 1 μH and about 10 mH. The size of the droop inductor, among other things, may be used to set specific features of the desired waveform, and the rate at which the waveform applied to the plasma can be adjusted.

The ion energy distribution can be an important factor in semiconductor plasma processing. For example, a relatively flat and low ion energy distribution with a spiked ion energy distribution at a specific energy level can improve etching or other processes. This may, for example, allow for most of the energy from the power supply to be concentrated in the plasma at a specific energy level. A high voltage pulsing power supplies disclosed in this document may be able to control the ion energy distribution within a plasma.

Real time feedback and control may be used to control the voltage waveform applied to the wafer. The voltage waveform may either be directly measured at or near the chamber or wafer (e.g., at point 134 and/or point 135) and/or calculated based on measurements of currents and voltages from other circuit elements. The amount of energy recovered and/or dissipated in the energy recovery circuit, for example, may be adjusted to create specific wafer voltage waveforms. The amount of current flowing through the droop inductor (e.g., droop inductor 187), for example, may be adjusted with real time feedback, for example, to optimize plasma and wafer etch parameters (e.g., ion energy distribution function). The timescale of the real time feedback and control may be faster than 1 Hz, 1 kHz, or 100 kHz. An active energy recovery circuit may allow for this real time feedback and control. A passive energy recovery circuit may also allow for real time feedback and control using variable passive elements, such as time variable resistors. Real time feedback and control adjustments may include, for example, the width of the positive portion of the pulse (e.g., rise time), the width of the negative portion of the pulse (e.g., fall time), the time between the positive and negative portions of the pulses, the pulse repetition frequency, the switch timing signals, etc. Numerous timing elements may be used to realize real time feedback and control. Real time feedback and control may be realized by varying the voltage applied to the pulsing power supply.

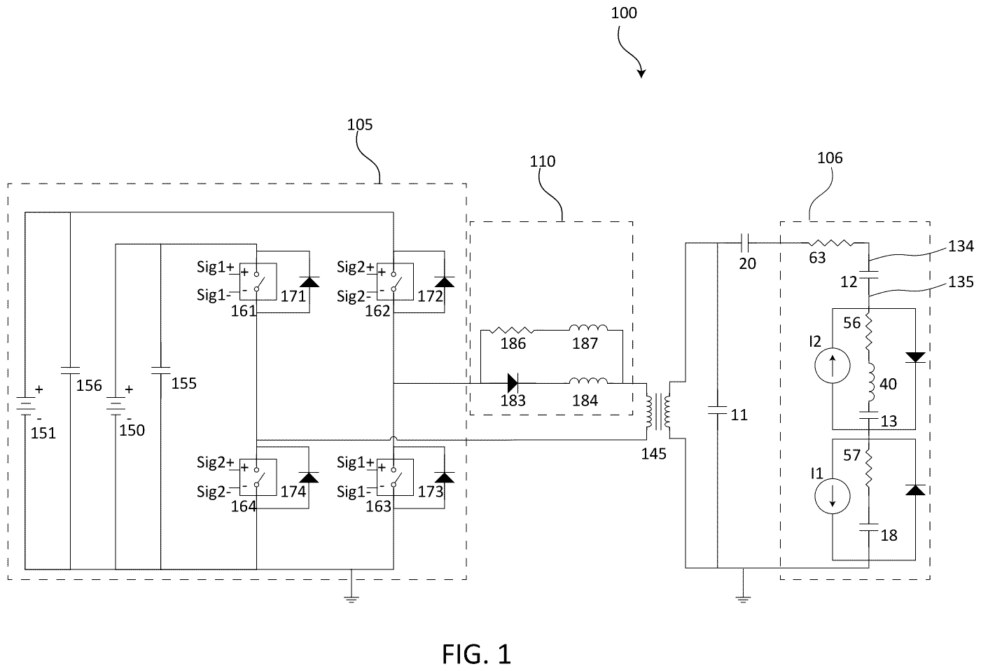

FIG. 1 is a circuit diagram of a high voltage pulsing power supply and plasma system 100. The high voltage pulsing power supply and plasma system 100, for example, may include a high voltage pulsing power supply 105 and a plasma chamber 106. The plasma chamber 106 represents the effective circuit of a plasma within a plasma chamber.

The high voltage pulsing power supply 105 is shown in a full bridge configuration but may also operate in a half bridge configuration or any other bridge configuration. The high voltage pulsing power supply 105 may include a plurality of switch modules in a full bridge configuration coupled with DC power supply 150 and energy storage capacitor 155 as well as DC power supply 151 and energy storage capacitor 156. The energy storage capacitor 156 and DC power supply 151 is switched by switch modules 162 and switch modules 164 to produce the positive pulse. The energy storage capacitor 155 and DC power supply 150 is switched by switch modules 161 and switch modules 163 to produce the negative of each pulse. The DC power supply 150 and DC power supply 151 may be the same supply and the energy storage capacitor 155 and the energy storage capacitor 156 may be the same capacitor charged to the same voltage. The charge voltage range of DC power supply 150 and DC power supply 151 may be between about 0 and about 1,000 V, or between about 0 and about 3,000 V, for example.

The high voltage pulsing power supply 105 may be coupled with a droop control circuit 110. The droop control circuit 110, for example, may be coupled with a transformer 145. The droop control circuit 110, for example, may mitigate or decrease the voltage droop within the plasma chamber such as, for example, on the wafer within the plasma chamber.

The high voltage pushing power supply and plasma system 100, for example, may produce bipolar pulses. A bipolar pulse, for example, may produce pulses that includes a positive pulse followed by a negative pulse. The bipolar pulse may be described as a single pulse that has both a positive and a negative pulse portion as shown in output waveform 205 and wafer waveform 210 in FIG. 2A and FIG. 2B. The peak-to-peak voltage between the positive pulse and the negative pulse may be greater than about 500 V, 1 kV, 2 kV, 5 kV, 10 kV, 15 kV, 20 kV, 100 kV, etc.

The high voltage pulsing power supply and plasma system 100, for example, may produce pulses that include a positive pulse having a peak voltage that may be greater than about 250 V, 500 V, 1 kV, 2 kV, 5 kV, 10 kV, 15 kV, 100 kV, etc. The high voltage pulsing power supply 105, for example, may produce pulses that include a negative pulse having a negative peak voltage that may be less than about −250 V, −500 V, −1 kV, −2 kV, −5 kV, −10 kV, −15 kV, −100 kV, etc.

The high voltage pulsing power supply and plasma system 100, for example, may produce pulses with high pulse repetition frequencies (e.g., frequencies greater than 1 kHz, 10 kHz, 100 kHz, 200 kHz, 500 kHz, 1 MHz, etc.), fast rise times (e.g., rise times less than about 1 ns, 10 ns, 50 ns, 100 ns, 250 ns, 500 ns, 1,000 ns, 10 μs, etc.), fast fall times (e.g., fall times less than about 1 ns, 10 ns, 50 ns, 100 ns, 250 ns, 500 ns, 1,000 ns, 10 μs, etc.) and/or short pulse widths (e.g., pulse widths less than about 10 μs, 1,000 ns, 500 ns, 250 ns, 100 ns, 20 ns, etc.).

The high voltage pulsing power supply and plasma system 100, for example, may produce pulses that include a combination of pulses that may include any combination of positive pulses, negative pulses, and/or bipolar pulses.

The high voltage pulsing power supply and plasma system 100, for example, may include a high voltage pulsing power supply 105. The high voltage pulsing power supply 105, for example, may be a half-bridge or a full-bridge circuit. The high voltage pulsing power supply 105 may include a DC power supply 150 with an energy storage capacitor 155.

The high voltage pulsing power supply 105, for example, may include four switch modules 161, 162, 163, 164. Each switch module of the switch modules 161, 162, 163, and 164, for example, may include any number of solid state switches arranged in series or parallel. The switch modules 161, 162, 163, and 164, for example, may include any type of solid-state switch such as, for example, IGBTs, a MOSFETs, a SiC MOSFETs, SiC junction transistors, FETs, SiC switches, GaN switches, photoconductive switches, etc. The switch modules 161, 162, 163, and 164 may be switched at high frequencies and/or may produce a high voltage pulses. These frequencies may, for example, include frequencies of about 10 kHz, 400 kHz, 0.5 MHz, 2.0 MHz, 4.0 MHz, 13.56 MHz, 27.12 MHz, 40.68 MHz, 50 MHz, etc. These frequencies may, for example, may be greater than 10 kHz. Each switch module 161, 162, 163, and 164 may or may not include the same number or same type of solid state switches as the other switch modules.

Each switch of switch modules 161, 162, 163, and 164 may include one or more solid state switches S1 (e.g., solid state switches such as, for example, IGBTs, a MOSFETs, a SiC MOSFETs, SiC junction transistors, FETs, SiC switches, GaN switches, photoconductive switches, etc.).

Each switch of switch modules 161, 162, 163, 164 may be coupled in parallel with a respective bridge diode 171, 172, 173, 174 and may include stray inductance and/or stray resistance. Multiple diodes may be used per switch, while some switches may have no diode associated with them, while other switches may share a common diode or diodes. The stray inductances of the switch modules, for example, may be equal. The stray inductances of the switch modules, for example, may be less than about 10 nH, 50 nH, 100 nH, 150 nH, 500 nH, 1,000 nH, etc. The stray inductance of each switch module, for example, may be less than about 200 nH. The stray inductance of each switch module, for example, may be between about 100 nH and about 500 nH. The combination of a switch module and a respective bridge diode may be coupled in series with a respective bridge inductor.

The transformer 145 (or the transformer T1), for example, may comprise a transformer such as, for example, as disclosed in U.S. patent application Ser. No. 15/365,094, titled “High Voltage Transformer,” which is incorporated into this document for all purposes.

For example, the duty cycle of the switch modules can be adjusted by changing the duty cycle of signal Sig1, which opens and closes switch module 161 and switch; changing the duty cycle of signal Sig2, which opens and closes switch module 162; changing the duty cycle of signal Sig3, which opens and closes switch module 163; and changing the duty cycle of signal Sig4, which opens and closes switch module 164.

Each switch module 161, 162, 163, or 164 in the high voltage pulsing power supply 105, for example, can be switched independently or in conjunction with one or more of the other switch modules. For example, the signal Sig1 may be the same signal as signal Sig3. As another example, the signal Sig2 may be the same signal as signal Sig4. As another example, each signal may be independent and may control each switch module 161, 162, 163, or 164 independently or separately.

The high voltage pulsing power supply and plasma system 100 may not include a traditional matching network such as, for example, a 50Ω matching network or an external matching network or standalone matching network. Indeed, the embodiments described within this document do not require a 50Ω matching network to tune the switching power applied to the wafer chamber. In addition, embodiments described within this document provide a variable output impedance RF generator without a traditional matching network. This can allow for rapid changes to the power drawn by the plasma chamber. Typically, this tuning of the matching network can take at least about 100 μs to about 200 μs. Power changes, for example, can occur within one or two RF cycles, for example, about 2.5 μs to about 5.0 μs at about 400 kHz.

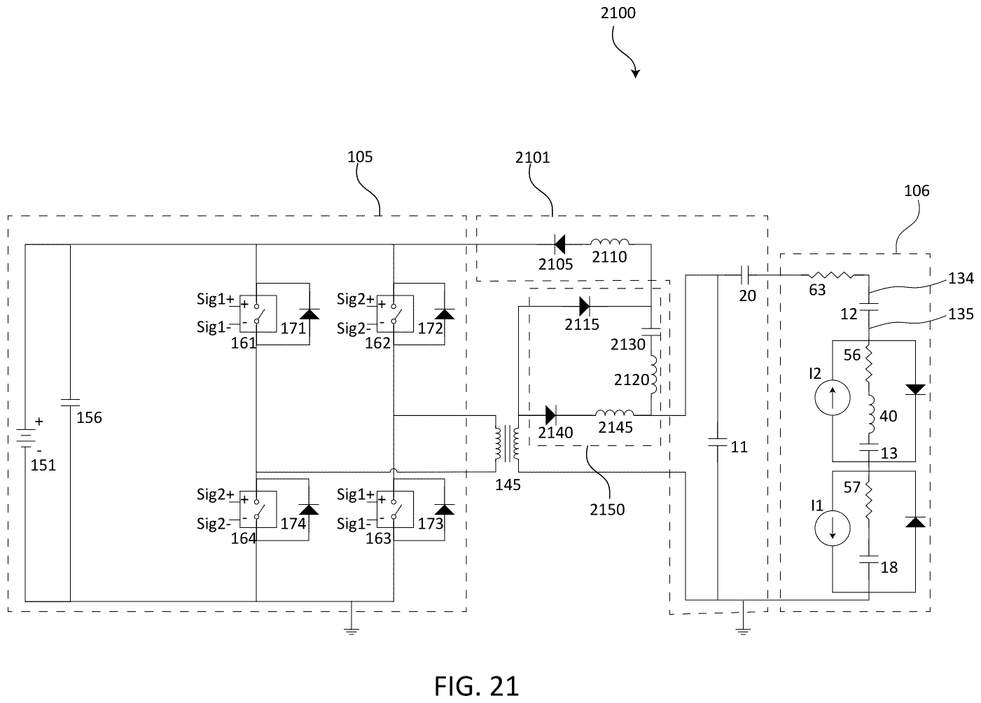

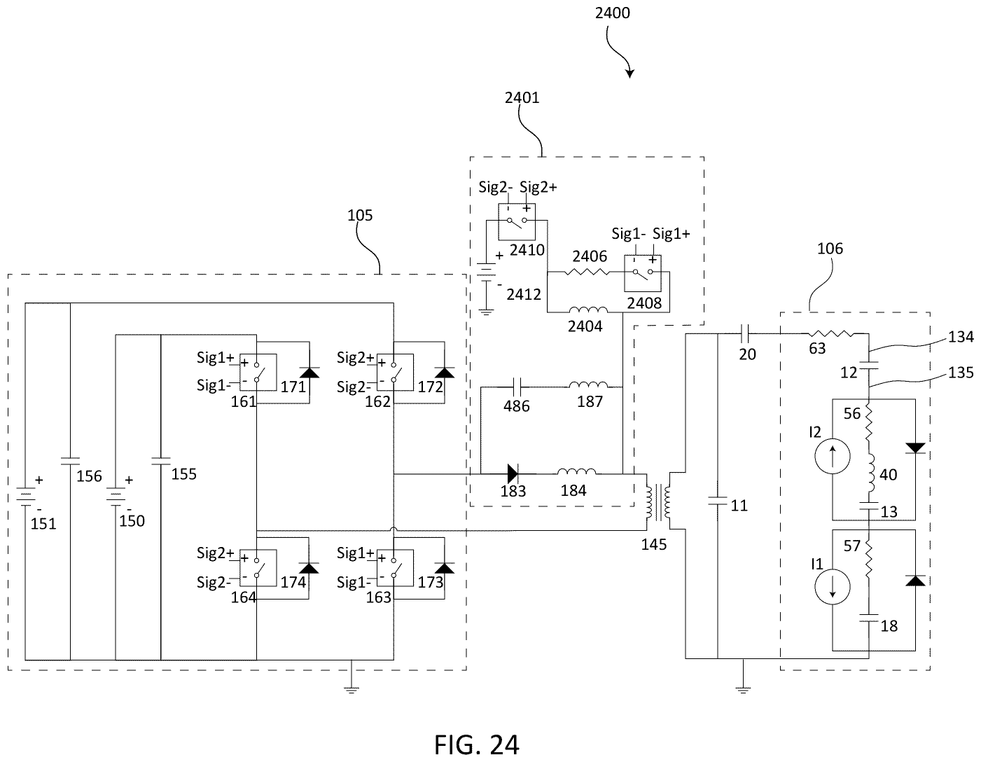

The high voltage pulsing power supply 105, for example, may be replaced with a half bridge circuit with two switch modules. The high voltage pulsing power supply 105, for example, may provide power in multiple configurations. For example, multiple power supply and energy storage capacitor combinations may be used to power the full bridge (or half bridge) as shown in FIG. 1 and FIG. 24. As another example, a single power supply and energy storage capacitor combination may be used to power the full bridge (or half bridge) as shown in FIG. 7, FIG. 12, and FIG. 21.

The droop control circuit 110 may include a droop inductor 187 coupled in series with droop resistor 186. The series combination of the droop inductor 187 and the droop resistor 186 may be arranged in parallel or across the droop diode 183 and/or inductor 184.

The droop diode 183, for example, may include one or more diodes arranged in series or parallel. The droop diode 183, for example, may be rated to carry currents greater than about 100 amps. The droop diode 183, for example, may be rated to carry currents greater than about 10, 100, 1000, 10,000, etc.

The inductor 184, for example, may include a physical inductor and/or represent a parasitic inductance and/or stray inductance. The parasitic inductance and/or stray inductance, for example, may include the inductance of components between the high voltage pulsing power supply 105 and the plasma chamber 106 and/or the inductance of the transformer 145. The inductor 184, for example, may have an inductance of about 0.1 nH, 1 nH, 10 nH, 100 nH, 1 μH, or 10 μH. The inductor 184, for example, may have an inductance less than about 500 nH.

The value of the inductance of the inductor 184, for example, may be set such that the positive going pulse has a nice sinusoidal top. If the value of the inductance of the inductor 184 is too small then the ring up on the positive pulse, for example, will be too short and a step in the positive pulse may appear later in time. If the value of the inductance of the inductor 184 is too small, for example, then oscillations may be seen across the top of the positive pulse. If the value of the inductance of the inductor 184 is too big, for example, the smooth sinusoidal top will not have time to complete, and the sinusoid may be truncated. If the value of the inductance of the inductor 184 is too big, for example, the positive pulse may be increasing when it is truncated by the transition to the negative going pulse.

The droop control circuit 110 controls the voltage ramp on the transformer 145 so the peak voltage is reached later in the pulse. The droop inductor 187 is energized during the negative voltage portions of a bipolar pulse while the droop resistor 186 extracts energy from the droop inductor 187. The shape of the applied negative pulse in combination with droop resistor 186 sets the equilibrium current in the droop inductor 187. The equilibrium current, for example, may have a pulse to pulse ripple that is less than 1%, 5%, 20%, or 100% of its average value. The droop inductor, for example, may have an inductance so that during a burst of pulses equilibrium is reached within less than the first 2, 5, 70, or 100 pulses. The droop inductor 187, for example, may have an inductance to allow the equilibrium current through the droop inductor 187 to be reached within less than 20 pulses. During a positive portion of a pulse of a bipolar pulse, the current flows through droop diode 183 and inductor 184 into the transformer 145.

The inductor 184, for example, may have an inductance of about 0.1 nH, 3 nH, 100 nH, or 10 μH. Typically it is set to be less than 200 nH. The droop inductor 187, for example, may have an inductance of about 1 μH, 10 μH, 100 μH, or 3000 μH.

The droop resistor 186, for example, may have a resistance of about 0.01 Ohm, 0.3 Ohms, 30 Ohms, or 100 Ohms. It is typically set less than 4 Ohms.

The plasma chamber 106, for example, may represent an idealized or effective circuit for semiconductor processing chamber such as, for example, a plasma deposition system, semiconductor fabrication system, plasma sputtering system, plasma etch system, etc. The capacitance of capacitor 12, for example, may represent the capacitance of an electrostatic chuck upon which a semiconductor process wafer may sit. The chuck, for example, may comprise a dielectric material (e.g., aluminum oxide, or other ceramic materials and a conductor housed within the dielectric material). For example, the capacitor 23 may have small capacitance (e.g., about 10 pF, 100 pF, 500 pF, 1 nF, 10 nF, 100 nF, etc.).

The capacitor 13, for example, may represent the sheath capacitance between the plasma to the wafer. The resistor 56, for example, may represent the sheath resistance between the plasma and the wafer. The inductor 40, for example, may represent the sheath inductance between the plasma and the wafer. The current source I2, for example, may be represent the ion current through the sheath. For example, the capacitor 23 or the capacitor 13 may have small capacitance (e.g., about 10 pF, 100 pF, 500 pF, 1 nF, 10 nF, 100 nF, etc.).

The capacitor 18, for example, may represent the plasma sheath capacitance to the wall of the chamber. The resistor 57, for example, may represent resistance between the plasma and the chamber wall. The current source I1, for example, may be representative of the ion current in the plasma. For example, the capacitor 23 or the capacitor 18 may have small capacitance (e.g., about 10 pF, 100 pF, 500 pF, 1 nF, 10 nF, 100 nF, etc.).

The plasma chamber may include one or more electrodes that can be used to ignite the plasma and/or to drive the plasma. One or more electrodes may be electrically coupled with a high voltage pulsing power supply.

FIG. 2A and FIG. 2B show an output waveform 205 at point 134 and a wafer waveform 210 at point 135 in the circuit of an example of the high voltage pulsing power supply and plasma system 100. The wafer waveform 210, for example, may show the voltage on a wafer within a plasma chamber such as, for example, a dielectric etch plasma chamber. The waveform 215 shows the switching logic of SIG±2 switch module 162 and switch module 164. The waveform 220 shows the switching logic of SIG±1 switch module 161 and switch module 163. As shown, the portion of the output waveform 205 between pulses has a negative slope, which causes the portion of the wafer waveform 210 between pulses to be substantially flat.

The output waveform 205, for example, was created with a charge voltage of 600 V from the DC power supply 151, a positive pulse width of 450 ns, and a negative pulse width of 1,950 ns. In this example, the droop inductor 187 is about 6 μH, the droop resistor 186 has a resistance of 0.5 ohms, and the inductor 184 has an inductance of about 16 nH. This may, for example, mitigate or decrease voltage droop within the plasma chamber such as, for example, on the wafer within the plasma chamber as shown by the flat portion of wafer waveform 210 between two positive pulses.

FIG. 2B also an example of two high voltage pulses. Each pulse of the wafer waveform 210 has a positive pulse portion 211 and a negative pulse portion 212. The positive pulse portion 211 is the portion of a pulse with a voltage greater than zero and the negative pulse portion 212 is the portion of the pulse below zero. Between the negative pulse portion 212 and the positive pulse portion 211 the pulse may have a fast rise time (i.e., steep positive slope). And between the positive pulse portion 211 and the negative pulse portion 212 the pulse may have a fast fall time (i.e., steep negative slope). The fall time, for example, may be slower than the rise time.

Between the positive pulse portion 211, for example, may have an upper relatively flat portion (or at least with a gradual rising and/or falling slope). The positive pulse portion 211 may have any length. The negative pulse portion 212, for example, may have lower relatively flat portion (or at least with a gradual rising and/or falling slope). The negative pulse portion 212, for example, may have any length. The negative pulse portion 212 may have a length longer than the positive pulse portion 211.

The height of the positive pulse portion 211 relative to the negative pulse portion 212 is the amplitude of the pulse. The time between consecutive positive pulse portions 211 may be the pulse period and the inverse of the pulse period may be the pulse repetition frequency. A pulsed waveform is not a sinusoidal waveform or an RF waveform. Indeed, an ideal pulsed waveform on the wafer (e.g., wafer waveform 210) is more like a square wave than a sinusoidal waveform. In addition, a sinusoidal waveform cannot have fast rise times and/or fast fall times with longer upper relatively flat portions and/or lower flat portions, which is not necessarily the case with pulse waveforms. In addition, in a sinusoidal waveform the positive pulse portion 211 and the negative pulse portion 212 have about the same length, whereas in a pulsed waveform, this is not necessarily the case.

The output waveform 205 in FIG. 2B shows an example droop 221 between pulses. As shown, a droop between pulses is a negative slope in the negative pulse portion 212.

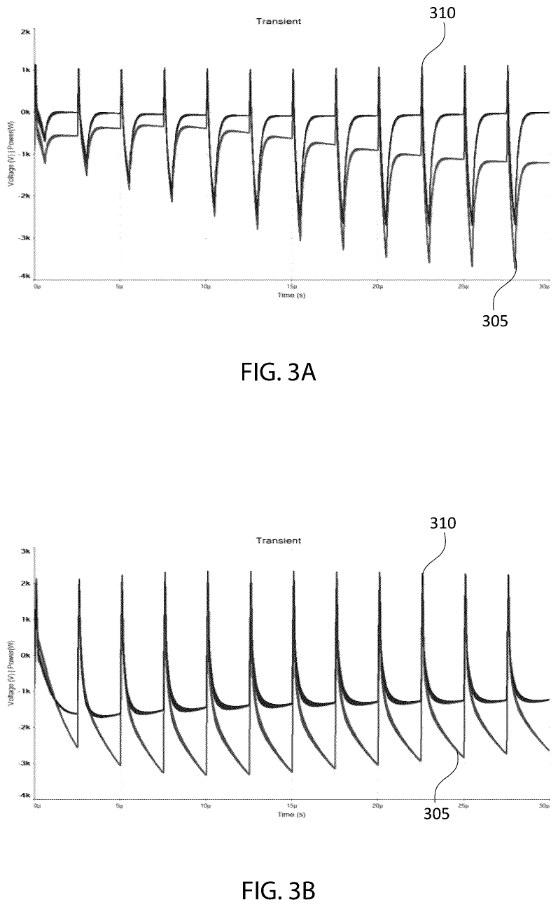

A lower output voltage, for example, may be achieved by adjusting the time constraints such that the charge voltage remains substantially constant. This may be referred to as multistate operation, which includes a series of pulses having different voltages. A multistate operation, for example, can be achieved by adjusting the positive and negative pulse width as shown in FIG. 3A and FIG. 3B, which show an output waveform 305 at point 134 and a wafer waveform 310 at point 135. In FIG. 3A, a positive pulse of 50 ns and negative pulse width of 350 ns is used. In FIG. 3B, the positive pulse width is 90 ns, and the negative pulse width is 2,310 ns.

A multistate operation, for example, may be achieved by increasing the value of the droop resistor 186, where higher resistance values may lead to lower output voltages. FIG. 3B shows a waveform where the droop resistor 186 was set to 6 Ohms, as opposed to the 0.5 Ohms used in generating FIG. 2B.

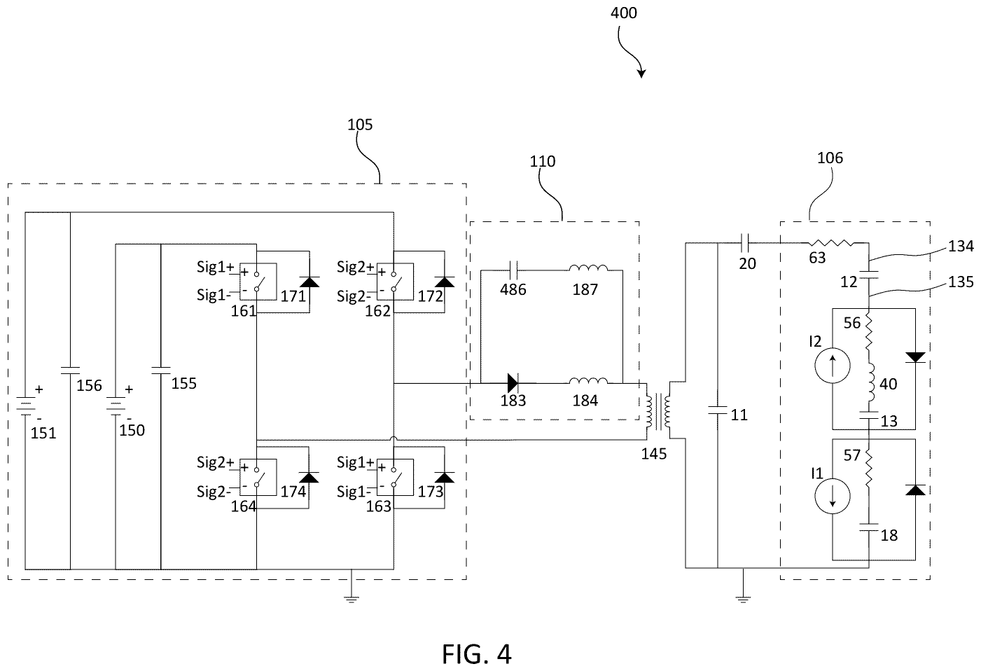

FIG. 4. is a circuit diagram of an example high voltage pulsing power supply and plasma system 400. The droop resistor 186 in plasma system 100 has been replaced with a droop capacitor 486 in series with the droop inductor 187. The droop capacitor 486, for example, may have a capacitance of about 10 mF, 25 mF, 50 mF, 100 mF, 250 mF, 500 mF, 1,000 mF, 38 F, 200 F, etc. The droop capacitor 486, for example, may extract energy from the droop inductor. While the droop resistor 186 dissipates energy as ohmic losses, the droop capacitor 486 may convert energy into stored capacitive energy. This stored energy may, for example, increase the potential difference across the droop capacitor 486. This stored energy, for example, may be recovered by an energy recovery circuit (e.g., energy recovery circuit 701 or active droop control circuit 1201 or energy compensation circuit 2101) such that the voltage across droop capacitor 486 remains approximately constant during a burst. The energy recovery circuit may, for example, include a DC-DC converter that maintains voltage on droop capacitor 486 while delivering excess energy to the high voltage pulsing power supply 105. When an energy recovery circuit is used, the droop capacitor 486 may have a value of less than about 100 mF, 10 mF 100 μF, 10 μF, or 1 μF. Typically the value is set to less than about 30 μF for full bridge topologies and about 100 μF for half bridge topologies.

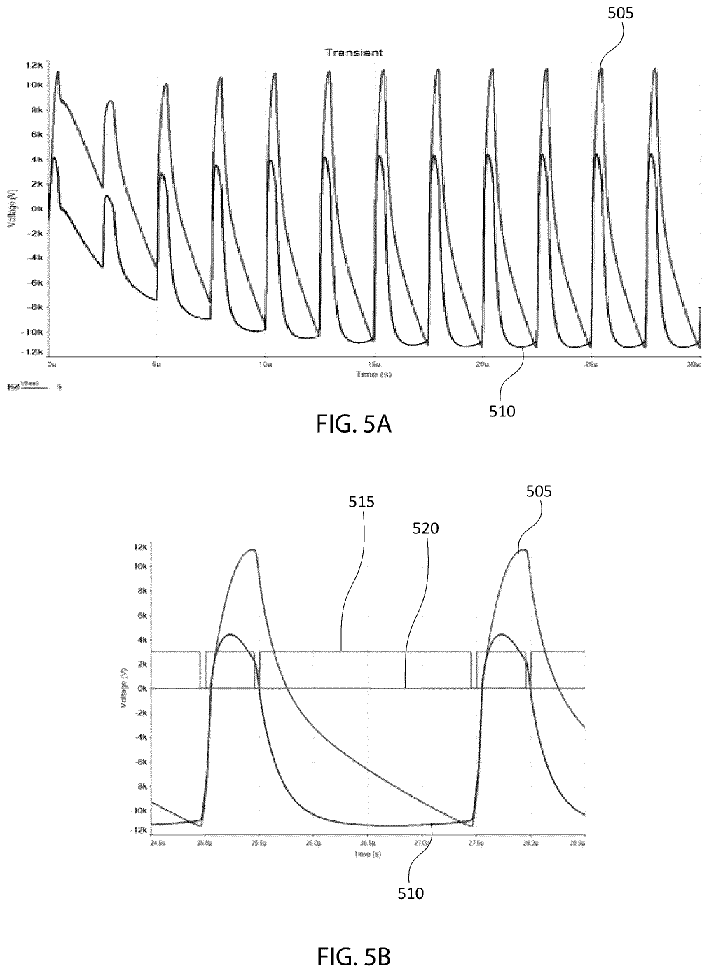

FIG. 5A and FIG. 5B show an output waveform 505 measured at point 134 of the high voltage pulsing power supply and plasma system 400 and the wafer waveform 510 is measured at point 135 in the circuit of an example of the high voltage pulsing power supply and plasma system 400. The wafer waveform 510, for example, may show the voltage on a wafer within a plasma chamber. The waveform 515 shows the switching logic of SIG±2 switch module 162 and switch 164. The waveform 520 show the switching logic of SIG±1 switch module 161 and switch 163. As shown, the portion of the output waveform 505 between pulses has a negative slope, which causes the portion of the wafer waveform 510 between pulses to be substantially flat.

The output waveform 505 and wafer waveform 510 can be created, for example, with a charge voltage of 600 V from the DC power supply with a 450 ns positive pulse width and 1950 ns negative pulse width. A −270 V initial charge may be added across the droop capacitor 486. In the example shown in FIG. 5A and FIG. 5B, the droop capacitor 486 may have a capacitance of about 200 mF.

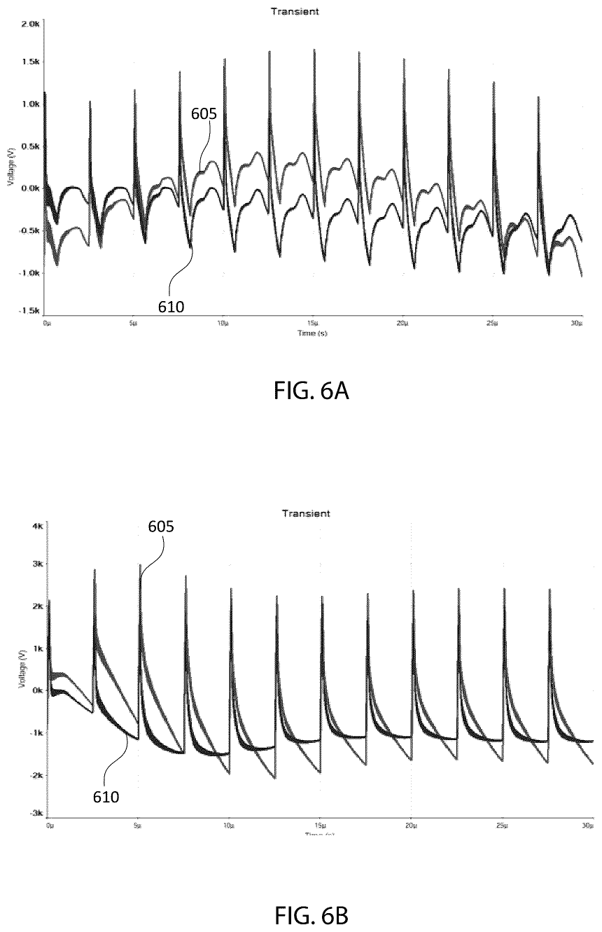

FIG. 6A and FIG. 6B show an output waveform 605 at point 134 and a wafer waveform 610 at point 135. FIG. 6A shows waveforms with a 50 ns positive pulse and a 350 ns negative pulse width. FIG. 6B shows waveforms with a 90 ns positive pulse, 2310 ns negative pulse, and −575 V initial charge voltage on the droop capacitor.

FIG. 7 is a circuit diagram of a high voltage pulsing power supply and plasma system 700 that may include power supply 705 coupled with plasma chamber 106. The high voltage pulsing power supply and plasma system 700 may include a droop control circuit 110 and/or an energy recovery circuit 701. The power supply 705 may be similar to the high voltage pulsing power supply 105 with a DC power supply 150 and an energy storage capacitor 155

The energy recovery circuit 701 is coupled with the droop inductor 187 of the droop control circuit 110. The energy recovery circuit 701 may also be coupled with the DC power supply 150 and the energy storage capacitor 155. The energy recovery circuit 701, for example, may include a DC-DC converter coupled between the droop control circuit 110 and the energy storage capacitor 155.

The energy recovery circuit 701 may include switch module 731 and switch module 732 arranged in a half bridge configuration (a full bridge configuration or other bridge configuration may also be used). Each switch module 731, 732 may include respective switch diode 741, 742. The energy recovery circuit 701 may also include a transformer 715 coupled with the switch module 731, and/or the switch module 732. The transformer 715 may be inductively coupled with a rectification bridge 730, which is coupled with the energy storage capacitor 155 through an energy recovery inductor 706 and/or an energy recovery diode 710. The energy recovery diode 710, for example, may allow charge from the droop capacitor 720 and/or the droop capacitor 725 to flow to charge the energy storage capacitor 155. The values of each of the elements in the energy recovery circuit may be set to allow the voltage on droop capacitor 720 and droop capacitor 725 to be varied in a time less than 2 pulses, 20 pulses, or 200 pulses, for example.

The energy recovery inductor 706, for example, may have a low inductance. The energy recovery inductor 706, for example, may have an inductance less than about 1 nH, 10 nH, 50 nH, 100 nH, 150 nH, 500 nH, 1,000 nH, etc. The energy recovery inductor 706, for example, may include the inductance of the rectification bridge 730, the transformer 715, the switch module 731, and/or the switch module 732.

The switch module 731 and/or the switch module 732, for example, can be switched on and off to control the amount of energy removed from the droop inductor 187. This can be done, for example, by adjusting the duty cycle of switch module 731 and/or switch module 732. This can be done, for example, based on feedback from one or more sensors monitoring the voltage at the capacitance 12.

The energy recovery circuit 701, for example, may transfer energy from the droop inductor 187 to charge the energy storage capacitor 155. The energy recovery circuit 701 is coupled across the droop capacitor 720 and/or droop capacitor 725.

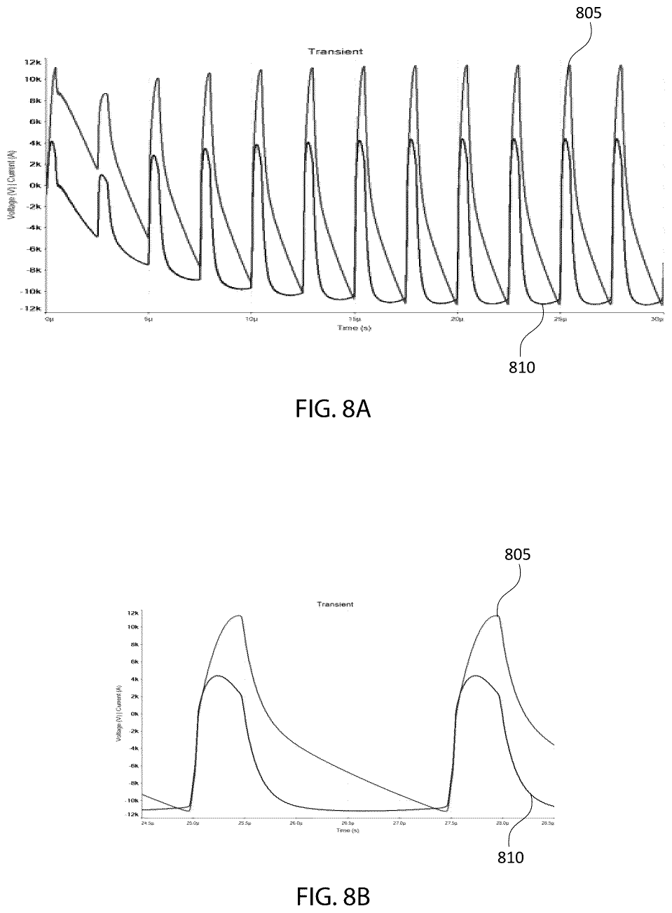

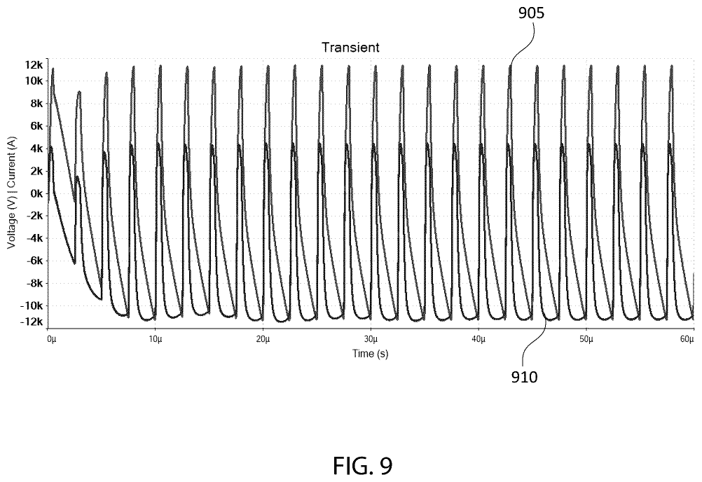

FIG. 8A and 8B show an output waveform 805 at point 134 and a wafer waveform 810 at point 135 in the circuit of an example of the high voltage pulsing power supply and plasma system 700. As shown, the portion of the output waveform 805 between pulses has a negative slope, which causes the portion of the wafer waveform 810 between pulses to be substantially flat.

In this example, the output can be created with a charge voltage of 600 V from the DC power supply with a 450 ns positive pulse width and 1950 ns negative pulse width. In this example, the switching frequency of switch module 731 and switch module 732 is set to 250 kHz. Typical frequencies of operation may be greater than 1 kHz, 10 kHz, 100 kHz, or 3 MHz. Each switch, in this example, is closed for about 1.65 μs, which amounts to an 8 about 2.5% duty cycle. In this example, an initial charge voltage is applied across the droop capacitor 720 and/or droop capacitor 725 of about −135 V, where the total initial charge voltage across the 2 capacitors is −270 V. In this example, each of the droop capacitor 720 and/or droop capacitor 725 have a capacitance of about 25 μF, though other values may be used such as less than about 1 μF, 33 μF, 500 μF, or 3 mF. The specific value of capacitance may be selected to set both the ripple in the plasma current and the rate at which the wafer voltage can be adjusted through the action of the energy recovery circuit. Typical adjustment times may be greater than about 0.1 μs, 1 ms, or about 10 minutes, for example. While this initial emf enables the output voltage to reach equilibrium quickly, the energy recovery circuit duty cycle sustains the equilibrium.

FIG. 9 shows an output waveform 905 at point 134 and a wafer waveform 910 at point 135 in the circuit of an example of the high voltage pulsing power supply and plasma system 700. In this example, no initial emf is applied to the droop capacitor 720 and/or droop capacitor 725. In this example, the output voltage still reaches equilibrium.

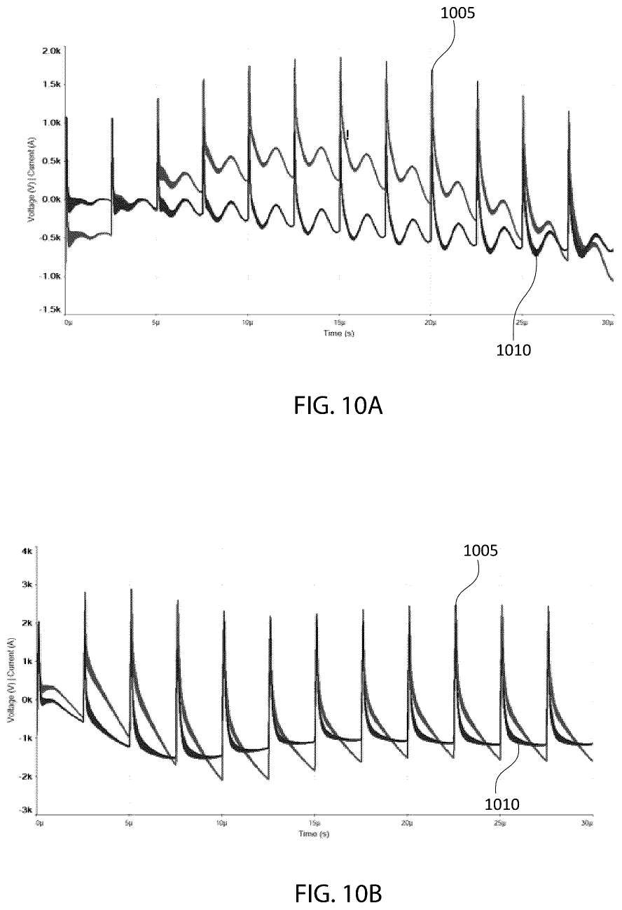

FIG. 10A and 10B show an output waveform 1005 at point 134 and a wafer waveform 1010 at point 135 in the circuit of an example of the high voltage pulsing power supply and plasma system 700. In this example, the circuit values are the same as those used to produce the waveforms shown in FIG. 8A and 8B, but the timings for FIG. 10A are 50 ns for the positive pulse and 350 ns for the negative pulse, and the timings for FIG. 10B are 90 ns for the positive portion of the pulse and 2310 ns for the negative portion of the pulse. In this example, the energy recovery circuit duty cycle is reduced to 15%. The duty cycle of the energy recovery circuit may range anywhere from 0% to 100% as is typical of DC to DC converters.

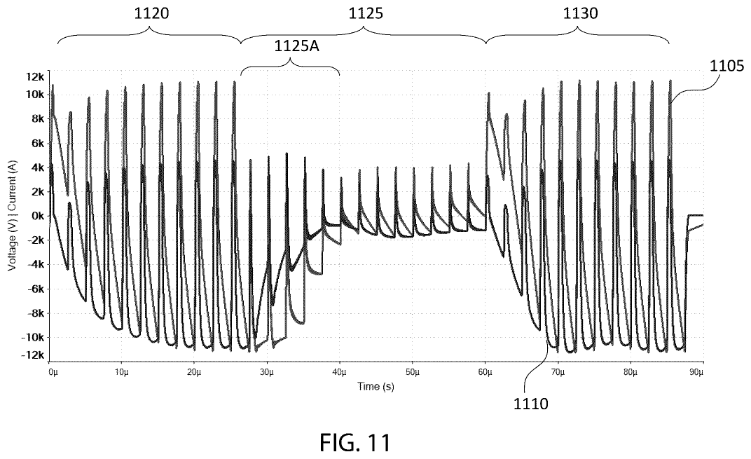

FIG. 11 show an output waveform 1105 at point 134 and a wafer waveform 1110 at point 135 in the circuit of an example of the high voltage pulsing power supply and plasma system 700. In this example, the output voltage switches between a high voltage burst 1120 of about 27.5 μs, a multi-state burst 1125 of about 32.5 μs, and a high voltage burst 1130 of about 27.5 μs. The transition occurred simply by using the energy recovery circuit to set/program the voltage across the droop capacitor 720 and/or the droop capacitor 725. Increasing the voltage across these capacitors may lead to lower voltage and/or multilevel operation, while decreasing the voltage across these capacitors may lead to higher voltage operation. By regulating the voltage across these capacitors, the energy recovery circuit, or DC to DC converter, can be used to create any general combination of output voltages, forming any desired time dependent pattern. During the transition from high voltage burst 1120 to multi-state burst 1125, the transformer flux can swing negative for a few transition bursts 1125A. The multistate positive pulse width, for example, can be adjusted and/or the multistate negative pulse width can be lowered to avoid saturating the transformer during this transition to reduce the amount of negative flux injected into the transformer core.

FIG. 12 is a circuit diagram of a high voltage pulsing power supply and plasma system 1200 with an active droop control circuit 1201. The active droop control circuit 1201, for example, may also include energy recovery elements (e.g., energy recovery inductor 1225 and diode 1226) that recover energy from the droop inductor 187 to the energy storage capacitor 156.

The high voltage pulsing power supply and plasma system 1200 includes a high voltage pulsing power supply 705 coupled with the active droop control circuit 1201 and the plasma chamber 106.

The active droop control circuit 1201, for example, may include droop inductor 187 coupled in series with droop capacitor 486 and second droop inductor 1205. The total droop inductance may be split evenly between the droop inductor 187 and the droop inductor 1205, or it may be divided unevenly between the droop inductor 187 and the droop inductor 1205. The exact division selected may simplify the design and construction of each of the individual inductors. A switch circuit (e.g., half bridge switch circuit or full bridge switch circuit) may be coupled across the droop capacitor 486. The switch circuit may also be coupled with transformer 1210.

The active droop control circuit 1201, for example, may include switch module 1215, switch module 1216, switch module 1217, switch module 1218, transformer 1210, diode rectification bridge 1220, energy recovery inductor 1225, and/or energy recovery diode 1226. The diode rectification bridge 1220, for example, may be coupled with or between the energy recovery inductor 1225 and transformer 1210. The energy recovery inductor 1225 may be coupled with the energy storage capacitor 156 that is part of the power supply 705.

Charge may be removed from and/or added to the droop capacitor 486 by controlling the timing of the switches in the active droop control circuit 1201. The active droop control circuit 1201 may be or include any converter that moves energy from droop capacitor 486 to energy storage capacitor 156 or moves energy from energy storage capacitor 156 to droop capacitor 486.

The active droop control circuit 1201, for example, may include or comprise any of various forms of a DC-DC converters. The active droop control circuit 1201, for example, may include a set of switches arranged in a bridge configuration, a transformer, a rectification stage, and a filter inductor. One example function of the active droop control circuit 1201 may be to regulate the voltage on droop capacitor 486. This may be done, for example, on the needed timescale to create the desired wafer voltage waveforms and/or plasma voltage waveforms.

Droop capacitor 486 may have a value of less than about 10 mF, 1 mF, 20 μF, or 1 μF. For example, droop capacitor 486 may have a value of less than about 100 μF. The specific value of the droop capacitor 486, for example, may be selected to allow and/or facilitate the ability of the active droop control circuit 1201 to adjust the voltage across droop capacitor 486 on the needed timescale. The timescale of adjustment may be greater than about 1 μs, 1 ms, or 1 hour. Smaller inductance values of the droop capacitor 486, for example, may allow for the faster adjustment of the output voltage, and thus the ability to both more rapidly adjust the ion energy distribution in a plasma, and the ability to more finely tune the composite ion energy distribution in the plasma that includes the sum of the individual ion energy distribution in the plasma.

The timescale for the active droop control circuit 1201 to adjust the voltage on droop capacitor 486 may be less than 2 pulses, 20 pulses, or 200 pulses, where each pulse may have a positive and negative portion that when combined last for 100 ns, 1 μs, 2.5 μs, 100 μs, or 1 ms. The timescale for the active droop control circuit 1201 to adjust the voltage on droop capacitor 486 may be considered fast for the typical 100 ms to 1 s timescales on which DC-DC converters typically operate/regulate voltages.

By regulating the voltage on droop capacitor 486, the active droop control circuit 1201, for example, may allow for control of the ion energy distribution in the plasma and/or allow for voltage droop control between pulses on the wafer. Either or both of these, for example, can be done in real time such as, for example, within about 100 μs, 10 μs, 5 μs, 1 μs, 500 ns, 250 ns, 100 ns, etc. There may be advantages to rapidly varying the voltage on droop capacitor 486, and/or to slowly varying it. When it is slowly varied, a relatively uniform ion energy distribution function may be realized pulse to pulse, while when it is rapidly varied, very different ion energy distribution functions may be realized pulse to pulse. The cumulative resultant ion energy distribution function may be the same whether the voltage across the chuck capacitance (e.g., capacitor 12) is varied slowly or quickly. However, by rapidly varying the voltage across droop capacitor 486, completely new and/or different cumulative ion energy distribution functions may be attained than can be realized by any individual pulse's ion energy distribution function.

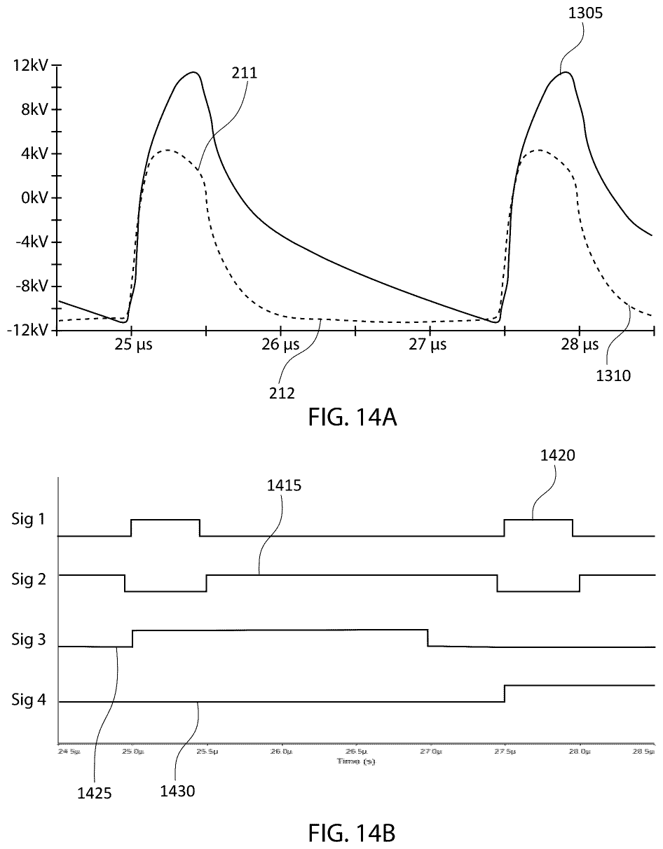

FIG. 13 shows waveforms having a series of pulses produced by the high voltage pulsing power supply and plasma system 1200. FIG. 14A shows a zoomed in version of two pulses, and FIG. 14B shows the various control waveforms used by the various switches to produce the waveforms shown in FIGS. 13 and 14A.

For example, output waveform 1305 is the waveform measured at point 134 and wafer waveform 1310 is a corresponding waveform measured at point 135. The output waveform 1305 shows the voltage at the at capacitor 12. The wafer waveform 1310 shows the voltage on a wafer within the plasma chamber. The control waveform 1420 shows the switching logic of SIG±2, which opens and closes the switch module 162 and switch module 164, which when closed generates the positive pulse portion 1305. The control waveform 1415 shows the switching logic of SIG±1, which opens and closes switch module 161 and switch module 163, which generates the negative pulse portion 1315. The energy recovery waveform 1425 shows the switching logic of SIG±3, which opens and closes ER switch 1215 and ER switch 1217, and the energy recovery waveform 1430 shows the switching logic of SIG±4, which opens and closes ER switch 1216 and ER switch 1218.

The positive pulse portion in waveform 1305 and waveform 1310 correspond with the closing of switch 161 and switch 163 by control waveform 1415, and the opening switch 162 and switch 164 with control waveform 1420. The peak and minimum voltages of the positive pulse portion and negative pulse portion in waveform 1305 and waveform 1310 may be proportional to the duration of either or both the on time of waveform 1425 and/or the on time of waveform 1430. The duration of the on time of waveform 1425 and 1430 may be used to set the voltage on droop capacitor 486. Varying the duration of the on time of waveform 1425 and 1430 may be used to vary the voltage on droop capacitor 486.

In addition, although the negative pulse portion of the output waveform 1305 has a negative slope or a droop, the negative pulse portion of the wafer waveform 1310 is substantially flat. In this example, the output waveform 1305 and wafer waveform 1310 can be created by the plasma system 1200, for example, with a charge voltage of 600 V from the DC power supply with a 450 ns positive pulse width and 1950 ns negative pulse width.

The waveforms shown in FIG. 13, FIG. 14A, and FIG. 14B were created using a droop capacitor having a capacitance of less than about 10 μF. The transformer 1201, for example, may have a low turns ratio such as, for example, a 3:1 or a 2:1 turns ratio, or the turns ratio may be set higher to be around 10:1 or 40:1. The specific value of the turns ratio selected will in part set both the ripple in the current flowing through the energy recovery circuit, and the rate at which the active droop control circuit 1201 can adjust the voltage on droop capacitor 486. The higher the turns ratio is set, the bigger the ripple in the current is, and the faster the active droop control circuit 1201 can adjust the voltage on droop capacitor 486. The switching frequency of switch modules 1215, 1216, 1217, 1218 may be about 200 kHz. Operating frequencies between about 1 kHz and about 10 MHz may be selected. As another example, each switch of switch modules 1215, 1216, 1217, 1218 may be closed for about 1.98 μs, and/or have a duty cycle of about 79.2%. The selected duty cycle may range between 0% and 100%, which allows the active droop control circuit 1201 to recover anywhere from its minimum to maximum amount of energy. The active droop control circuit 1201 may be any form of DC to DC converter.

FIG. 12 shows a full bridge topology. Many other DC to DC converter topologies is possible. The DC to DC converter topology may be designed to allow the voltage on droop capacitor 486 to be adjusted rapidly, for example in less than 100 μs, 10 μs, or 1 μs. It may also allow the voltage on droop capacitor 486 to be adjusted very slowly, for example in greater than 1 s, 1000 s, or 1 day. The standard operation of the active droop control circuit 1201 may allow the voltage across droop capacitor 486 to map out whatever waveform is desired, on any time timescale between very fast and very slow. Some of the plasma processes may require rapid voltage adjustment, while others may require the plasma conditions to be slowly adjusted over hours to days.

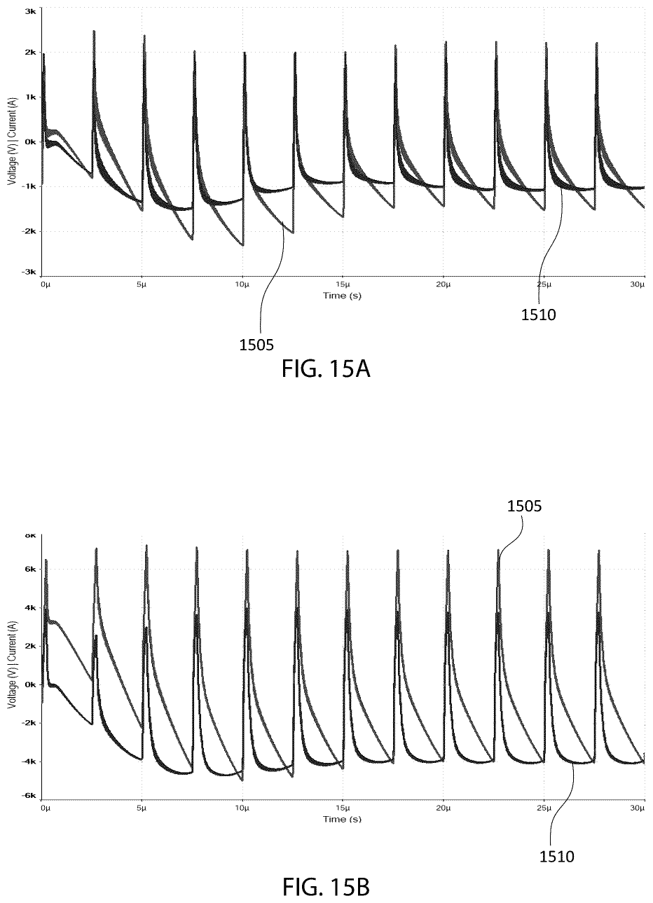

The active droop control circuit 1201 may, for example, allow for operation at a range of wafer voltages without changing the input charging voltage. For example, by changing the positive and negative pulse widths of switch modules 1215, 1216, 1217, 1218 and/or the duty cycle of the switch modules 1215, 1216, 1217, 1218 the duration of the negative wafer voltage time can be increased and/or the output voltage may be increased. FIG. 15A shows a wafer waveform 1510 having a 1 kV wafer voltage generated by the plasma system 1200 with an 85 ns positive pulse, a 2315 ns negative pulse, and a 300 ns energy recovery pulse from switch modules 1215, 1216, 1217, 1218. FIG. 15B shows a wafer waveform 1510 having a 4 kV wafer voltage generated by the plasma system 1200 with a 200 ns positive pulse width, a 2200 ns negative pulse, and a 730 ns energy recovery pulse from switch modules 1215, 1216, 1217, 1218.

A process for creating the waveforms shown in FIG. 14A using the logic represented by the waveforms in FIG. 14B is also disclosed. For example, at a first time, the process may include closing a first switch module (e.g., switch module 162 and/or switch module 164) and opening a second switch module (e.g., switch module 161 and/or switch module 163) of a high voltage pulsing power supply 705 to produce a positive pulse portion 211 of a first high voltage pulse 1305. The positive pulse portion, for example, may have an amplitude greater than about 1 kV.

At about the first time or shortly thereafter, the process may include closing a third switch module (e.g., switch module 1216 and/or switch module 1218) and opening a fourth switch module (e.g., switch module 1215 and/or switch module 1217) of an energy recovery circuit 2101.

At a second time after the first time, the process, for example, may include opening the first switch module (e.g., switch module 162 and/or switch module 164) and closing the second switch module (e.g., switch module 161 and/or switch module 163) to produce a negative pulse portion 212 of the first high voltage pulse.

At a third time after the second time, the process, for example, may include opening the third switch module.

At a fourth time after the third time, the process, for example, may include closing the first switch module and opening the second switch module to produce another positive pulse portion of a second high voltage pulse, the positive pulse portion having an amplitude greater than about 1 kV.

At about the fourth time or shortly thereafter, the process, for example, may include closing the fourth switch module at about the fourth time.

At a fifth time after the fourth time, the process, for example, may include opening the first switch module and closing the second switch module to produce a negative pulse portion of the second high voltage pulse.

FIG. 16A shows output waveform 1600 at point 134 and wafer waveform 1610 at point 135 in the circuit of an example of the high voltage pulsing power supply and plasma system 1200. In this example, the output waveform 1600 and the wafer waveform 1610 have four different voltage states (e.g., first state 1605, second state 1610, third state 1615, and fourth state 1620) that are controlled by changing the pulse width and/or the duty cycle of the switches in the active droop control circuit 1201 and/or the pulse width of the pulses produced by the power supply 705, and or the pulse widths driving the switches in the energy recovery circuit. The energy recovery control waveform 1625 controls the switching logic of SIG±3, which opens and closes ER switch 1215 and ER switch 1217 and the energy recovery waveform 1630 shows the switching logic of SIG±4, which opens and closes ER switch 1216 and ER switch 1218, where ER is an abbreviation of energy recovery.

The first state 1605, for example, has a duration of about 22.5 μs and a negative voltage of about −10 kV. The first state 1605, for example, may be produced by a 450 ns positive pulse width (+PW) and 1950 ns negative pulse width (−PW) from the power supply 705 and a symmetric 1980 ns pulse width at about 200 kHz from the active droop control circuit 1201.

The second state 1610, for example, has a duration of about 22.5 μs and a negative voltage of about −7.5 kV. The second state 1610 may be produced by a 320 ns positive pulse width (+PW) and 2080 ns negative pulse width (−PW) from the power supply 705 and a symmetric 1200 ns pulse width at about 200 kHz from the active droop control circuit 1201.

The third state 1615, for example, has a duration of about 22.5 μs and a negative voltage of about −5 kV. The third state 1615 may be produced by a 215 ns positive pulse width (+PW) and 2185 ns negative pulse width (−PW) from the power supply 705 and a symmetric 1020 ns pulse width at about 200 kHz from the active droop control circuit 1201.

The fourth state 1620, for example, has a duration of about 22.5 μs and a negative voltage of about −2.5 kV. The fourth state 1620 may be produced by a 115 ns positive pulse width (+PW) and 2285 ns negative pulse width (−PW) from the power supply 705 and a symmetric 900 ns pulse width at about 200 kHz from the active droop control circuit 1201.

Various other voltage states with different durations and voltages can be created by changing the pulse width and/or the duty cycle of the switches in the active droop control circuit 1201 and/or the pulse width of the pulses produced by the power supply 705. DC power supply 151 may also be adjusted to create various voltage states.

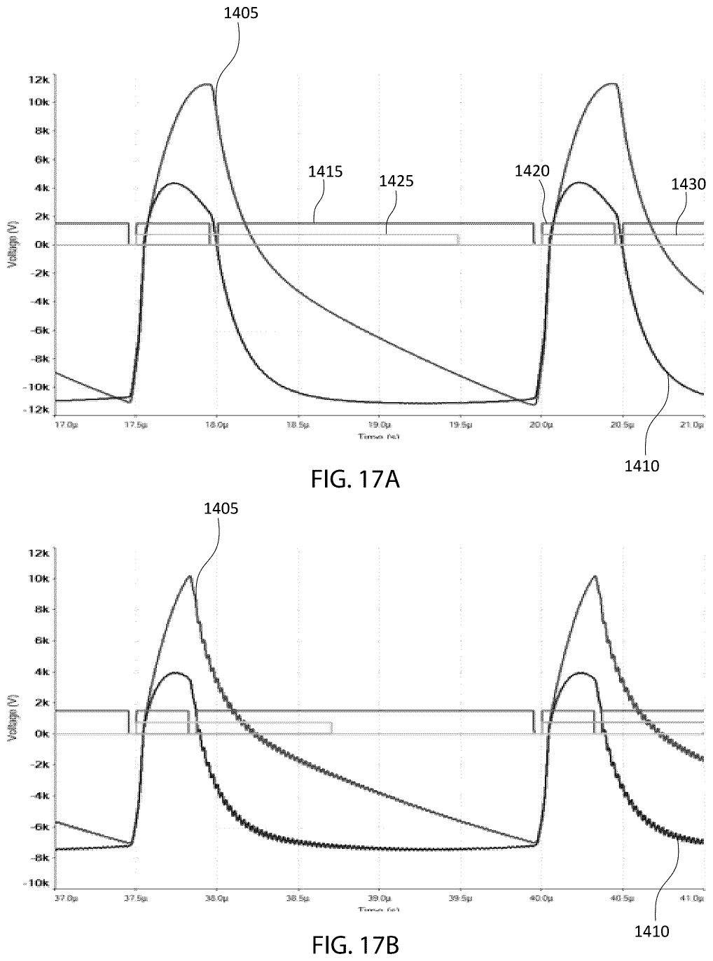

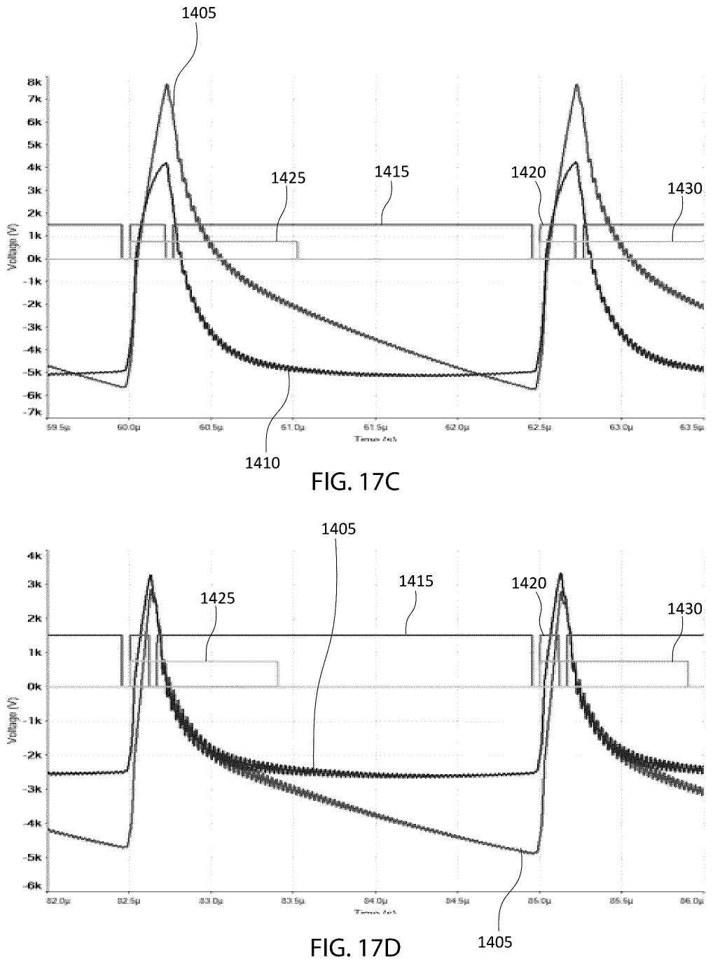

FIG. 17A shows zoomed in views of the waveform shown in FIG. 16A at approximately 20 μs showing two pulses within the first state 1605 along with the control waveform 1415, control waveform 1420, energy recovery waveform 1425, and energy recovery waveform 1430.

FIG. 17B shows zoomed in views of the waveform shown in FIG. 16A at approximately 40 μs showing two pulses within the second state 1610 along with the control waveform 1415, control waveform 1420, energy recovery waveform 1425, and energy recovery waveform 1430.

FIG. 17C shows zoomed in views of the waveform shown in FIG. 16A at approximately 60 μs showing two pulses within the third state 1615 along with the control waveform 1415, control waveform 1420, energy recovery waveform 1425, and energy recovery waveform 1430.

FIG. 17D shows zoomed in views of the waveform shown in FIG. 16A at approximately 80 μs showing two pulses within the fourth state 1620 along with the control waveform 1415, control waveform 1420, energy recovery waveform 1425, and energy recovery waveform 1430.

The timing of all control waveforms may be continuously adjusted across all relevant or needed time ranges to create the desired output waveforms. The timing precision of the waveform adjustment may be less than 1 s, 1 ms, 1 μs, 1 ns, or less, as needed to create the desired waveforms. Specific waveforms or patterns of waveforms will typically be selected to optimize a particular plasma process, such as for example increasing the rate of plasma etch, controlling the width of the features etched, controlling the aspect ratio of features eted, controlling the mask etch rate, etc. The waveforms may be adjusted to control a wide variety of plasma processes and features. By adjusting the output waveforms, the resultant ion energy distribution function may be adjusted. The voltage across droop capacitor 486 and all the switch timings may be adjusted to adjust the output waveforms, the output current, the resultant ion energy distribution function, and any number of specific plasma and/or etch features. This invention specifically allows for the ability to adjust plasma and etch parameters, such as the ion energy distribution function, over a wide and often continuous operating space. It can do this in a steady state fashion where all pulses are the same with a specific ion energy distribution function, or by modulating the output pulses to create aggregate waveforms with a specific aggregate ion energy distribution function. During any particular etch prosses, it may be advantageous to continuously optimize the ion energy distribution function through the etch process.

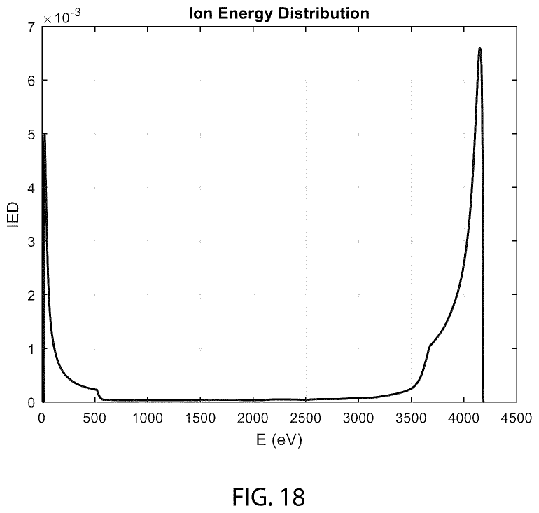

FIG. 18 shows an ion energy distribution function (ion energy distribution function) for ions within the plasma chamber 106 of the plasma system 1200 with the pulses and configuration described in conjunction with FIG. 17B.

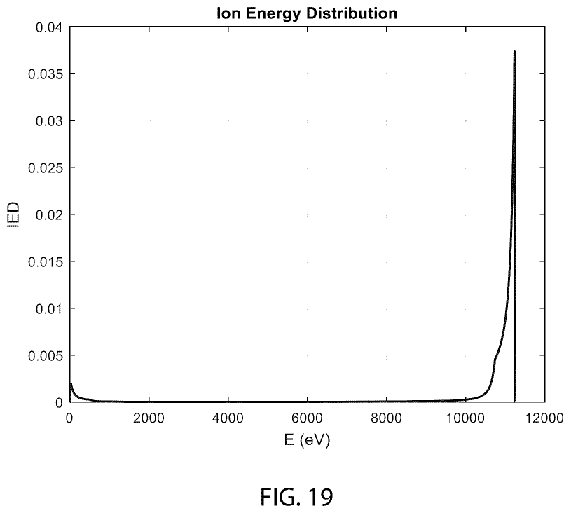

FIG. 19 shows an ion energy distribution for ions within the plasma chamber 106 of the plasma system 1200 with the pulses and configuration described in conjunction with FIG. 17A.

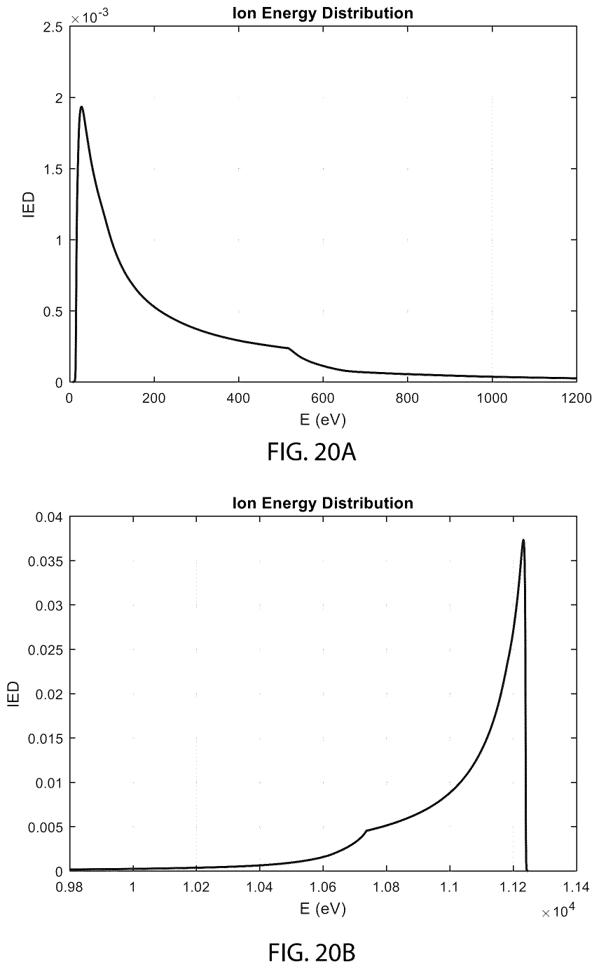

FIG. 20A shows the low end energy distribution function shown in FIG. 19 and FIG. 20B shows the high end energy distribution function shown in FIG. 19. The plasma system 1200 can produce an ion energy distribution that is substantially flat for various ion energies, which may lead to wafer voltage that is nearly constant for extended periods.

FIG. 21 is a circuit diagram of a high voltage pulsing power supply and plasma system 2100 with a droop control circuit 2150, and an energy control circuit 2101. The droop control circuit 2150 includes a diode 2140 coupled in series with inductor 2145. Positive going pulses from the secondary side of the transformer 145 pass through diode 2140 and inductor 2145 to plasma chamber 106. FIG. 21 shows an instance where the droop control elements and energy recovery elements have been placed on the secondary of the transformer. In general, the droop control elements and active droop control circuit 1201 may be placed either on the primary side of the transformer or the secondary side of the transformer. The overall function of the elements is the same, though the specific values used are scaled by the turns ratio of the transformer, with inductors becoming larger by the square of the turns ratio, and capacitors becoming smaller by the square of the turns ratio.

The series combination of the droop inductor 2120 and the droop capacitor 2130 may be arranged in parallel or across the diode 2140 and/or inductor 2145. The droop control circuit 2101 controls the voltage ramp on the transformer 145 so the peak voltage is reached later in the pulse. The droop inductor 2120 is energized during the negative voltage portions of a bipolar pulse and once the full charge voltage is present on the inductor 2145 or the plasma chamber 106, an equilibrium is reached where energy is extracted from the droop inductor 2120 during the positive pulse at a rate roughly equal to which it is gained. During a positive pulse of a bipolar pulse, the current flows from the secondary side of the transformer 145 through diode 2140 and inductor 2145 to the plasma chamber 106.

Capacitor 2130 may also be a resistor or an inductor. If it is a capacitor, it may be coupled with an active energy recovery circuit that regulates the voltage across capacitor 2130 in order to select the desired output voltage waveforms.

The energy compensation circuit 2101 is coupled with the secondary side of the transformer 145 and with energy storage capacitor 156. The energy compensation circuit 2101, for example, includes an energy recovery diode 2105 and an energy recovery inductor 2110. The energy recovery diode 2105 and the energy recovery inductor 2110 may be coupled with the secondary side of the transformer 145 via diode 2115 and droop control circuit. Inductor 2105 may have a value greater than 1 μH, 10 μH, 100 μH, or 10 mH.

FIG. 22 shows the ion energy distribution for ions within the plasma chamber 106 of the plasma system 2100 (or any of the plasma systems disclosed in this document).

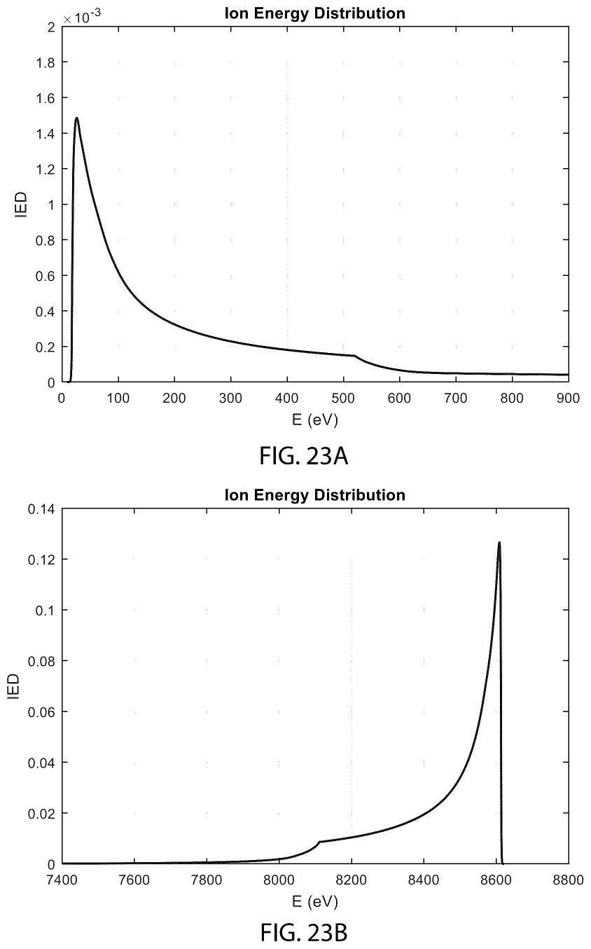

FIG. 23A shows the low end of the ion energy distribution shown in FIG. 22 and FIG. 23B shows the high end of the ion energy distribution shown in FIG. 22. The plasma system 2100 (or any of the plasma systems disclosed in this document) can produce an ion energy distribution that is substantially flat for various ion energies (e.g., substantially flat for a substantial portion of ion energies) and peaked in a narrow band of ion energies, which may lead to wafer voltage that is nearly constant for extended periods. By adjusting the various droop control and energy recovery elements, any number of potential ion energy distribution functions can be created, Specific elements may be adjusted in real time to maintain specific plasma parameters, or to sweep across or control various plasma parameter ranges.

FIG. 24 is a circuit diagram of a high voltage pulsing power supply and plasma system 2400 with an active droop control circuit 2401. The high voltage pulsing power supply and plasma system 2400 includes the high voltage pulsing power supply 105 coupled with the active droop control circuit 2401 and the plasma chamber 106. The active droop control circuit may be operated in a way to create various output waveforms and various ion energy distribution functions in a manner that is equivalent to the operation of the droop control and active energy recovery circuits described above. FIG. 24 is yet another instance of this creation.

The active droop control circuit 2401, for example, may be coupled with the droop inductor 187 on the primary side of the transformer 145. The active droop control circuit 2401 can add and/or remove charge from the droop capacitor 486. When switch 2408 is closed and switch 2410 is open, charge stored in the droop capacitor 486 can be dissipated into the resistor 2406. The resistor 2406, for example, may have a resistance of about 0.1 Ohm, 3 Ohms, or 367 Ohms.

When the switch 2408 is open and the switch 2410 is closed, the droop capacitor 486 may be charged from the voltage source 2412 through the inductor 2404. The voltage source 2412, for example, may have a voltage of about 0 V, 100 V, 500 V or 5000 V for example. The voltage source 2412, for example, may provide a voltage that is always within about 10 V, 300 V or 5000 V of the DC power supply 150 and/or DC power supply 151.

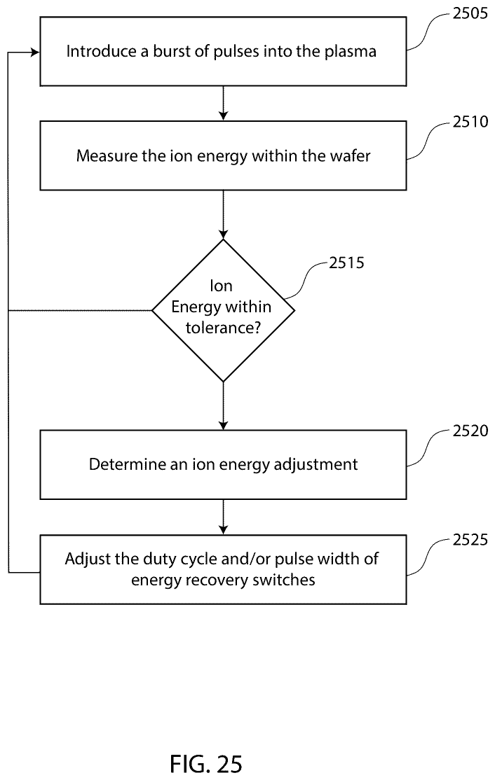

FIG. 25 is a flowchart of an example process 2500 for controlling the ion energy distribution on a wafer. At block 2505 a plurality of high voltage pulses (e.g., a burst of pulses) are introduced into a plasma via a high voltage pulser. The process 2500 may be operable for plasma system 2400, plasma system 2100, and/or 1200.

At block 2510 the ion energy distribution on the wafer can be measured, estimated, or calculated. The ion energy distribution on the wafer can be estimated by measuring the voltage out of the pulsing power supply, the voltage at capacitor 12, the current out of the pulsing power supply, and/or the plasma density within the chamber.

At block 2515, it can be determined whether the ion energy distribution on the wafer, if any, is within tolerances. If it is, then process 2500 can return to block 2505. If it is not, then process 2505 can proceed to block 2520.

At block 2520, an ion energy distribution adjustment can be determined based on the measured ion energy distribution and/or on a prescribed or desired ion energy distribution.

At block 2525, the duty cycle and/or the pulse width (open/close duration) of energy recovery switches can be adjusted. Process 2500 can then return to block 2505.

Numerous other control processes for this system may be envisioned. The parameters that can be measured and/or adjusted using some/any form of real time feedback and control include all aspects of the output voltage and current waveforms, any and/or all switch timings, various component values, ion energy distribution functions, and any number of the plasma and/or etch parameters. For example, the voltage across the droop capacitor 720 and/or the droop capacitors 725 may be controlled to maintain a specific etch rate, aspect ratio, mask erosion rate, and/or feature size. For example, the output voltage waveform may be monitored and set in real time to maintain a specific ion energy distribution function, or to map out/sweep out a specific set of ion energy distribution functions. The ion energy distribution functions selected may be selected to optimize one or many specific etch parameters such as, for example, etch rate, aspect ratio, and/or feature size. For example, the droop rate might be varied to control the mask erosion rate.

FIG. 26 is an illustration of an example waveform with two ideal bursts of pulses: first burst 2605 and second burst 2606. A single burst may include a plurality of pulses 2610. A burst duration is the time period when a burst is on, Tₒₙ, and the burst is off, T_{off}. A pulse width, P_{width}, is the period of time that the pulse is on. The pulse period, P_{period}, is the time period when the pulse is on and off. The duty cycle may be represented by the on time, Tₒₙ, divided by the burst duration:

$$DC = \frac{{T}_{o n}}{{T}_{o n} + {T}_{off}} .$$

The burst repetition frequency can be represented by the reciprocal of the burst period: f_{burst}=1/(Tₒₙ+T_{off}). The pulse repetition frequency can be represented by the reciprocal of the pulse period: fₚᵤₗₛₑ=1/P_{period}.

A positive waveform has bursts of pulses with the lowest voltage V₀ and the pulse amplitude V₁ both above zero. A negative waveform has bursts of pulses with lowest voltage V₀ and the pulse amplitude V₁ both below zero. A bipolar waveform has bursts of pulses with lowest voltage V₀ below zero and the pulse amplitude V₁ above zero.

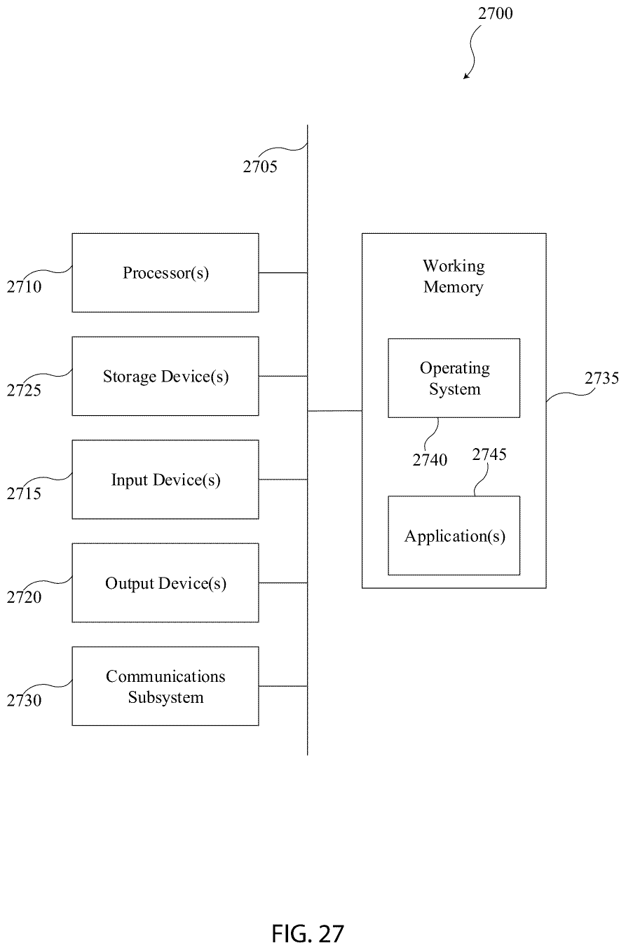

The computational system 2700, shown in FIG. 27 can be used to perform any of the embodiments of the invention. For example, computational system 2700 can be used to execute any or all of process 2500 and/or any of the feedback and control processes discussed above. As another example, computational system 2700 can perform any calculation, identification and/or determination described in this document. Computational system 2700 includes hardware elements that can be electrically coupled via a bus 2705 (or may otherwise be in communication, as appropriate). The hardware elements can include one or more processors 2710, including without limitation one or more general-purpose processors and/or one or more special-purpose processors (such as digital signal processing chips, graphics acceleration chips, and/or the like); one or more input devices 2715, which can include without limitation a mouse, a keyboard and/or the like; and one or more output devices 2720, which can include without limitation a display device, a printer and/or the like.

The computational system 2700 may further include (and/or be in communication with) one or more storage devices 2725, which can include, without limitation, local and/or network accessible storage and/or can include, without limitation, a disk drive, a drive array, an optical storage device, a solid-state storage device, such as a random access memory (“RAM”) and/or a read-only memory (“ROM”), which can be programmable, flash-updateable and/or the like. The computational system 2700 might also include a communications subsystem 2730, which can include without limitation a modem, a network card (wireless or wired), an infrared communication device, a wireless communication device and/or chipset (such as a Bluetooth device, an 802.6 device, a Wi-Fi device, a WiMax device, cellular communication facilities, etc.), and/or the like. The communications subsystem 2730 may permit data to be exchanged with a network (such as the network described below, to name one example), and/or any other devices described in this document. In many embodiments, the computational system 2700 will further include a working memory 2735, which can include a RAM or ROM device, as described above.

The computational system 2700 also can include software elements, shown as being currently located within the working memory 2735, including an operating system 2740 and/or other code, such as one or more application programs 2745, which may include computer programs of the invention, and/or may be designed to implement methods of the invention and/or configure systems of the invention, as described herein. For example, one or more procedures described with respect to the method(s) discussed above might be implemented as code and/or instructions executable by a computer (and/or a processor within a computer). A set of these instructions and/or codes might be stored on a computer-readable storage medium, such as the storage device(s) 2725 described above.

In some cases, the storage medium might be incorporated within the computational system 2700 or in communication with the computational system 2700. In other embodiments, the storage medium might be separate from a computational system 2700 (e.g., a removable medium, such as a compact disc, etc.), and/or provided in an installation package, such that the storage medium can be used to program a general-purpose computer with the instructions/code stored thereon. These instructions might take the form of executable code, which is executable by the computational system 2700 and/or might take the form of source and/or installable code, which, upon compilation and/or installation on the computational system 2700 (e.g., using any of a variety of generally available compilers, installation programs, compression/decompression utilities, etc.) then takes the form of executable code.

The above general description and the associated optimization/operating space description may generally apply to all of the circuits disclosed in the description or any of the drawings in one form or another. All the circuits may operate in a similar way; for example, where a brief positive pulse may reset the system and cancel the buildup of charge on the wafer from the previously flowing ion current; where the current in the droop inductor (e.g., droop inductor 187) may set the voltage on the wafer and/or may reduce, eliminate, or reverse any voltage droop; where the current may be set by balancing of the energy that flows into the droop inductor with the energy that flows out of the droop inductor (e.g., by balancing the positive volt seconds across the inductor with the negative volt seconds); and/or where the net energy balance of the energy that flows into and out of the droop inductor may be set by the energy recovery circuit, whether the energy recovery circuit is active or passive in nature.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed are not limited to any particular hardware architecture or configuration. A computing device can include any suitable arrangement of components that provides a result conditioned on one or more inputs. Suitable computing devices include multipurpose microprocessor-based computer systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained in software to be used in programming or configuring a computing device.

Embodiments of the methods disclosed may be performed in the operation of such computing devices. The order of the blocks presented in the examples above can be varied—for example, blocks can be re-ordered, combined, and/or broken into sub-blocks. Certain blocks or processes can be performed in parallel.

The use of “adapted to” or “configured to” is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. A high voltage pulsing power supply system comprising:
a DC power supply;
a switch circuit electrically coupled with the DC power supply, the switch circuit comprising a plurality of switch modules arranged in a full bridge configuration, the switching circuit produces a plurality of pulses having a positive pulse portion, a negative pulse portion, and an amplitude greater than about 10 kV;
a transformer comprising:
a transformer core;
a primary windings wound around the transformer core; and
a secondary winding wound around the transformer core;
a droop control circuit electrically coupled with the switch circuit and the primary winding, the droop control circuit comprising:
a droop diode electrically coupled in series between the switch circuit and the primary winding that allows the negative pulse portion of the plurality of pulses to pass from the switching circuit to the primary winding of the transformer; and
a droop inductor and a droop element arranged in series across the droop diode that allows the negative pulse portion of the plurality of pulses to pass from the switching circuit to the primary winding of the transformer and stores energy from the negative pulse portion of the plurality of pulses; and
an output electrically coupled with the secondary winding that outputs the plurality of pulses with a substantially flat negative pulse portion.

2. The high voltage pulsing power supply according to claim 1, wherein the droop element comprises a capacitor or a resistor.

3. The high voltage pulsing power supply according to claim 1, wherein the droop inductor has an inductance between about 1 μH and about 10 mH.

4. The high voltage pulsing power supply according to claim 1, further comprising an energy recovery circuit electrically coupled with the droop element and the high voltage power supply and comprising one or more switch modules that open and close to add or remove charge to or from the droop element.

5. The high voltage pulsing power supply according to claim 1, wherein the high voltage pulsing power supply is coupled with a plasma chamber having a plasma, and wherein the output produces an ion energy distribution that is substantially flat for a substantial portion of ion energies and peaked in a narrow band of ion energies.

6. The high voltage pulsing power supply according to claim 4, wherein the one or more switch modules of the energy recovery circuit are arranged in a full bridge or half bridge configuration.

7. The high voltage pulsing power supply according to claim 4, wherein the energy recovery circuit includes a diode and inductor arranged in series between the droop element and the high voltage power supply.

8. The high voltage pulsing power supply according to claim 4, wherein the energy recovery circuit includes a DC-DC converter.

9. The high voltage pulsing power supply according to claim 1, further comprising a plasma chamber having one or more electrodes, the one or more electrodes electrically coupled with the output, wherein the plurality of pulses produce an ion energy distribution within the plasma that is substantially flat for a substantial portion of ion energies and peaked in a narrow band of ion energies.

10. A plasma system comprising:
a DC power supply;
a switch circuit electrically coupled with the DC power supply, the switch circuit comprising a plurality of switch modules arranged in a full bridge configuration, the switching circuit produces a plurality of pulses having a positive pulse portion, a negative pulse portion, and an amplitude greater than about 10 kV;
a transformer comprising:
a transformer core;
a primary windings wound around the transformer core; and
a secondary winding wound around the transformer core;
a droop control circuit electrically coupled with the switch circuit and the primary winding, the droop control circuit comprising:
a droop diode electrically coupled in series between the switch circuit and the primary winding that allows the negative pulse portion of the plurality of pulses to pass from the switching circuit to the primary winding of the transformer; and
a droop inductor and a droop capacitor arranged in series across the droop diode that allows the negative pulse portion of the plurality of pulses to pass from the switching circuit to the primary winding of the transformer and stores energy from the negative pulse portion of the plurality of pulses;
an energy recovery circuit electrically coupled with the droop capacitor and the high voltage power supply, the energy recovery circuit comprising one or more switch modules that open and close to add or remove charge to or from the droop capacitor; and
a plasma chamber having one or more electrodes, the one or more electrodes electrically coupled with the secondary winding, wherein the plurality of pulses produce an ion energy distribution within the plasma that is substantially flat for a substantial portion of ion energies and peaked in a narrow band of ion energies.

11. The high voltage pulsing power supply according to claim 10, wherein the plurality of pulses comprises a substantially flat negative pulse portion.

12. The high voltage pulsing power supply according to claim 10, wherein the droop inductor has an inductance between about 1 μH and about 10 mH.

13. The high voltage pulsing power supply according to claim 10, wherein the energy recovery circuit includes a DC-DC converter.

14. The high voltage pulsing power supply according to claim 10, wherein the energy recovery circuit includes a transformer between the plurality of switch modules and the DC-DC converter.

15. The high voltage pulsing power supply according to claim 10, wherein the energy recovery circuit comprises an energy recovery inductor and a diode arranged in series between the high voltage power supply and the one or more switch modules.

16. The high voltage pulsing power supply according to claim 10, wherein the one or more switch modules of the energy recovery circuit are arranged in a full bridge or half bridge configuration.

17. A high voltage pulsing power supply system comprising:
a DC power supply;
a switch circuit electrically coupled with the DC power supply, the switch circuit comprising a plurality of switch modules arranged in a full bridge configuration, the switching circuit produces a plurality of pulses having a positive pulse portion, a negative pulse portion, and an amplitude greater than about 10 kV;
a transformer comprising:
a transformer core;
a primary windings wound around the transformer core; and
a secondary winding wound around the transformer core;
a droop control circuit electrically coupled with the switch circuit and the primary winding, the droop control circuit comprising:
a droop diode electrically coupled in series between the switch circuit and the primary winding that allows the negative pulse portion of the plurality of pulses to pass from the switching circuit to the primary winding of the transformer; and
a droop inductor and a droop capacitor arranged in series across the droop diode that allows the negative pulse portion of the plurality of pulses to pass from the switching circuit to the primary winding of the transformer and stores energy from the negative pulse portion of the plurality of pulses;
an energy recovery circuit electrically coupled with the droop capacitor, the energy recovery circuit comprising a plurality of switch modules arranged in a half-bridge or full-bridge arrangement and a DC-DC converter, the plurality of switch modules open and close to add or remove charge to or from the droop capacitor; and
an output electrically coupled with the secondary winding that outputs the plurality of pulses with a substantially flat negative pulse portion.

18. The high voltage pulsing power supply according to claim 17, further comprising a plasma chamber having one or more electrodes, the one or more electrodes electrically coupled with the output, wherein the plurality of pulses produce an ion energy distribution within the plasma that is substantially flat for a substantial portion of ion energies and peaked in a narrow band of ion energies.

19. The high voltage pulsing power supply according to claim 17, wherein the droop inductor has an inductance between about 1 μH and about 10 mH.

20. The high voltage pulsing power supply according to claim 17, wherein the energy recovery circuit comprises an energy recovery inductor and a diode arranged in series between the high voltage power supply and the DC-DC converter.

21. A method comprising:
producing a first burst of high voltage pulses into a plasma chamber having a plasma within the plasma chamber, the burst of high voltage pulses having a plurality of high voltage pulses having a first duty cycle, each high voltage pulse of the plurality of high voltage pulses having a pulse amplitude greater than 1 kV and a first pulse width;
estimating the ion energy distribution function within the plasma;
comparing the estimated ion energy distribution function with a required ion energy distribution function; and
in the event the estimated ion energy function differs from the required ion energy distribution function more than a threshold amount:
determining either or both a second duty cycle and a second pulse width based on the difference between the estimated ion energy function and the required ion energy distribution function; and
producing a second burst of high voltage pulses into a plasma chamber having a plasma within the plasma chamber, the burst of high voltage pulses having a plurality of high voltage pulses having a second duty cycle, each high voltage pulse of the plurality of high voltage pulses having a pulse amplitude greater than 1 kV and a second pulse width.

22. A method comprising:
closing a first switch module and opening a second switch module of a high voltage pulsing power supply to produce a positive pulse portion of a first high voltage pulse at a first time, the positive pulse portion having an amplitude greater than about 1 kV;
closing a third switch module and opening a fourth switch module of an energy recovery circuit at about a first time;
opening the first switch module and closing the second switch module to produce a negative pulse portion of the first high voltage pulse at a second time, wherein the second time is after the first time;
opening the third switch module at a third time, wherein the third time is after the second time;
closing the first switch module and opening the second switch module to produce a positive pulse portion of a second high voltage pulse, the positive pulse portion having an amplitude greater than about 1 kV at a fourth time, wherein the fourth time is after the third time;
closing the fourth switch module at about the fourth time; and
opening the first switch module and closing the second switch module to produce a negative pulse portion of the second high voltage pulse at a fifth time, wherein the fifth time is after the fourth time.
